(19) United States
(12) Patent Application Publication
(10) Pub. No.: US 2025/0270241 A1
(43) Pub. Date: Aug. 28, 2025

(54) HIGH PURITY TIN COMPOUNDS AND RELATED COMPOSITIONS AND RELATED METHODS

(71) Applicant: ENTEGRIS, INC., Billerica, MA (US)

(72) Inventor: David M. Ermert, Danbury, CT (US)

(21) Appl. No.: 19/063,008

(22) Filed: Feb. 25, 2025

Related U.S. Application Data
(60) Provisional application No. 63/558,066, filed on Feb. 26, 2024.

(51) Int. Cl. C07F 7/22

(52) U.S. Cl. CPC C07F 7/2224

(57) ABSTRACT

Compositions comprising tin (IV) alkoxide compounds useful for extreme ultraviolet lithography are provided. The compositions comprise a highly pure tin (IV) alkoxide compound, with low levels of impurities, including, for example and without limitation, at least one of halide impurities, ammonium impurities, or any combination thereof. Halide-free methods for synthesizing the tin (IV) alkoxide compounds are also provided. Various other compositions and methods are provided.

### CROSS-REFERENCE TO RELATED APPLICATIONS

This application claims the benefit under 35 USC 119 of U.S. Provisional Patent Application No. 63/558,066, filed Feb. 26, 2024, the disclosure of which is hereby incorporated herein by reference in its entirety.

### FIELD

The present disclosure relates to high purity tin compounds and related compositions and related methods.

### BACKGROUND

Some precursors are useful in the manufacture of microelectronic devices. The manufacture of such devices can involve use of extreme ultraviolet (EUV) lithography to form thin films.

### SUMMARY

Some embodiments relate to a composition comprising:
a tin (IV) alkoxide compound of the formula:

Sn(OR¹)₄,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof,
wherein a purity of the tin (IV) compound in the composition is at least 95%.

Some embodiments relate to a composition comprising:
a tin (IV) alkoxide compound of the formula:

Sn(OR¹)ₙ(OR)₄₋ₙ,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof,
wherein a purity of the tin (IV) alkoxide compound in the composition is at least 95%.

Some embodiments relate to a method comprising:
contacting a tin (IV) carboxylate compound with a reagent to form a tin (IV) alkoxide compound,
wherein the tin (IV) carboxylate compound comprises a compound of the formula:

Sn(O₂CR)₄,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
wherein the reagent comprises a compound of the formula:

MOR¹,
where:
M is an alkali metal cation, an alkaline earth metal cation, a transition metal cation, or a post-transition metal cation;
R¹ comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
wherein the tin (IV) alkoxide compound comprises a compound of the formula:

Sn(OR¹)₄,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

Some embodiments relate to a method comprising:
contacting a tin (IV) amide compound with a reagent to form a tin (IV) alkoxide compound,
wherein the tin (IV) amide compound comprises a compound of the formula:

Sn(NR₂)₄,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
wherein the reagent comprises a compound of the formula:

HOR¹,
where:
R¹ comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
wherein the tin (IV) alkoxide compound comprises a compound of the formula:

Sn(OR¹)₄,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a schematic diagram of a flowchart of a method for synthesizing a tin (IV) alkoxide compound, according to some embodiments.

FIG. 2 is a schematic diagram of a flowchart of a method for synthesizing a tin (IV) alkoxide compound, according to some embodiments.

FIG. 3 is a schematic diagram of a flowchart of a method for forming a film, according to some embodiments.

FIG. 4 is a schematic diagram of a reaction scheme illustrating a synthesis of a tin (IV) alkoxide compound, according to some embodiments.

FIG. 5 is a schematic diagram of a reaction scheme illustrating a synthesis of a tin (IV) alkoxide compound, according to some embodiments.

FIG. 6 is a graphical view of a thermogravimetric analysis of the Sn(O^{t}Bu)₄ product, according to some embodiments.

FIG. 7 is an NMR spectra of reaction products for varying amounts of HO^{t}Bu reagent, where A) 1 equivalent of HO^{t}Bu reagent, B) 2 equivalents of HO^{t}Bu reagent, and C) 3 equivalents of HO^{t}Bu reagent, according to some embodiments.

FIG. 8 is a graphical view of a thermogravimetric analysis of the Sn(O^{t}Am)₄ product, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “contacting” refers to bringing two or more components into immediate or close proximity, or into direct contact.

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, neo-pentyl, n-hexyl, isohexyl, 3-methylhexyl, 2-methylhexyl, heptyl, octyl, nonyl, decyl, dodecyl, octadecyl, or any combination thereof. In some embodiments, the alkyl is methyl. In some embodiments, the alkyl is isopropyl. In some embodiments, the alkyl is tert-butyl. In some embodiments, the term “alkyl” refers generally to alkyls, alkenyls, alkynyls, and/or cycloalkyls.

As used herein, the term “alkenyl” refers to a hydrocarbyl having from 1 to 30 carbon atoms and at least one carbon-carbon double bond. In some embodiments, the alkenyl comprises or is selected from the group consisting of at least one of a C₁-C₃₀ alkenyl, C₁-C₂₉ alkenyl, C₁-C₂₈ alkenyl, C₁-C₂₇ alkenyl, C₁-C₂₇ alkenyl, C₁-C₂₆ alkenyl, C₁-C₂₅ alkenyl, C₁-C₂₄ alkenyl, C₁-C₂₃ alkenyl, C₁-C₂₂ alkenyl, C₁-C₂₁ alkenyl, C₁-C₂₀ alkenyl, C₁-C₁₉ alkenyl, C₁-C₁₈ alkenyl, C₁-C₁₇ alkenyl, C₁-C₁₆ alkenyl, C₁-C₁₅ alkenyl, C₁-C₁₄ alkenyl, C₁-C₁₃ alkenyl, C₁-C₁₂ alkenyl, C₁-C₁₁ alkenyl, C₁-C₁₀ alkenyl, a C₁-C₉ alkenyl, a C₁-C₈ alkenyl, a C₁-C₇ alkenyl, a C₁-C₆ alkenyl, a C₁-C₅ alkenyl, a C₁-C₄ alkenyl, a C₁-C₃ alkenyl, a C₁-C₂ alkenyl, a C₂-C₃₀ alkenyl, a C₃-C₃₀ alkenyl, a C₄-C₃₀ alkenyl, a C₅-C₃₀ alkenyl, a C₆-C₃₀ alkenyl, a C₇-C₃₀ alkenyl, a C₈-C₃₀ alkenyl, a C₉-C₃₀ alkenyl, a C₁₀-C₃₀ alkenyl, a C₁₁-C₃₀ alkenyl, a C₁₂-C₃₀ alkenyl, a C₁₃-C₃₀ alkenyl, a C₁₄-C₃₀ alkenyl, a C₁₅-C₃₀ alkenyl, a C₁₆-C₃₀ alkenyl, a C₁₇-C₃₀ alkenyl, a C₁₈-C₃₀ alkenyl, a C₁₉-C₃₀ alkenyl, a C₂₀-C₃₀ alkenyl, a C₂₁-C₃₀ alkenyl, a C₂₂-C₃₀ alkenyl, a C₂₃-C₃₀ alkenyl, a C₂₄-C₃₀ alkenyl, a C₂₅-C₃₀ alkenyl, a C₂₆-C₃₀ alkenyl, a C₂₇-C₃₀ alkenyl, a C₂₈-C₃₀ alkenyl, a C₂₉-C₃₀ alkenyl, a C₂-C₁₀ alkenyl, a C₃-C₁₀ alkenyl, a C₄-C₁₀ alkenyl, a C₅-C₁₀ alkenyl, a C₆-C₁₀ alkenyl, a C₇-C₁₀ alkenyl, a C₈-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₃-C₅ alkenyl, or any combination thereof. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof. In some embodiments, the alkenyl is vinyl. In some embodiments, the alkenyl is an isopropenyl.

As used herein, the term “alkynyl” refers to a hydrocarbyl having from 1 to 30 carbon atoms and at least one carbon-carbon triple bond. In some embodiments, the alkynyl comprises or is selected from the group consisting of at least one of a C₁-C₃₀ alkynyl, C₁-C₂₉ alkynyl, C₁-C₂₈ alkynyl, C₁-C₂₇ alkynyl, C₁-C₂₇ alkynyl, C₁-C₂₆ alkynyl, C₁-C₂₅ alkynyl, C₁-C₂₄ alkynyl, C₁-C₂₃ alkynyl, C₁-C₂₂ alkynyl, C₁-C₂₁ alkynyl, C₁-C₂₀ alkynyl, C₁-C₁₉ alkynyl, C₁-C₁₈ alkynyl, C₁-C₁₇ alkynyl, C₁-C₁₆ alkynyl, C₁-C₁₅ alkynyl, C₁-C₁₄ alkynyl, C₁-C₁₃ alkynyl, C₁-C₁₂ alkynyl, C₁-C₁₁ alkynyl, C₁-C₁₀ alkynyl, a C₁-C₉ alkynyl, a C₁-C₈ alkynyl, a C₁-C₇ alkynyl, a C₁-C₆ alkynyl, a C₁-C₅ alkynyl, a C₁-C₄ alkynyl, a C₁-C₃alkynyl, a C₁-C₂ alkynyl, a C₂-C₃₀ alkynyl, a C₃-C₃₀ alkynyl, a C₄-C₃₀ alkynyl, a C₅-C₃₀ alkynyl, a C₆-C₃₀ alkynyl, a C₇-C₃₀ alkynyl, a C₈-C₃₀ alkynyl, a C₉-C₃₀ alkynyl, a C₁₀-C₃₀ alkynyl, a C₁₁-C₃₀ alkynyl, a C₁₂-C₃₀ alkynyl, a C₁₃-C₃₀ alkynyl, a C₁₄-C₃₀ alkynyl, a C₁₅-C₃₀ alkynyl, a C₁₆-C₃₀ alkynyl, a C₁₇-C₃₀ alkynyl, a C₁₈-C₃₀ alkynyl, a C₁₉-C₃₀ alkynyl, a C₂₀-C₃₀ alkynyl, a C₂₁-C₃₀ alkynyl, a C₂₂-C₃₀ alkynyl, a C₂₃-C₃₀ alkynyl, a C₂₄-C₃₀ alkynyl, a C₂₅-C₃₀ alkynyl, a C₂₆-C₃₀ alkynyl, a C₂₇-C₃₀ alkynyl, a C₂₈-C₃₀ alkynyl, a C₂₉-C₃₀ alkynyl, a C₂-C₁₀ alkynyl, a C₃-C₁₀ alkynyl, a C₄-C₁₀ alkynyl, a C₅-C₁₀ alkynyl, a C₆-C₁₀ alkynyl, a C₇-C₁₀ alkynyl, a C₈-C₁₀ alkynyl, a C₂-C₉ alkynyl, a C₂-C₈ alkynyl, a C₂-C₇ alkynyl, a C₂-C₆ alkynyl, a C₂-C₅ alkynyl, a C₃-C₅ alkynyl, or any combination thereof. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “cycloalkyl” refers to a non-aromatic carbocyclic ring having from 3 to 8 carbon atoms in the ring. The term includes a monocyclic non-aromatic carbocyclic ring and a polycyclic non-aromatic carbocyclic ring. The term “monocyclic,” when used as a modifier, refers to a cycloalkyl having a single cyclic ring structure. The term “polycyclic,” when used as a modifier, refers to a cycloalkyl having more than one cyclic ring structure, which may be fused, bridged, spiro, or otherwise bonded ring structures. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “aryl” refers to a monocyclic or polycyclic aromatic hydrocarbon. The number of carbon atoms of the aryl may be in a range of 5 carbon atoms to 100 carbon atoms. In some embodiments, the aryl has 5 to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. In some embodiments, the aryl is —C₆H₅. In some embodiments, the aryl is a phenyl.

As used herein, the term “amino” refers to a functional group of formula —N(R^{a}R^{b}), wherein R^{a} and R^{b} are independently a hydrogen, an alkyl (as defined herein), or a silyl (as defined herein), or R^{a} and R^{b} are bonded to each other to form a C₃-C₂₀ N-heterocycle. In some embodiments, the amino may comprise an alkylamino or a dialkylamino. In some embodiments, the amino may comprise at least one of methylamino, dimethylamino, ethylamino, diethylamino, isopropylamino, di-isopropylamino, butylamino, sec-butylamino, tert-butylamino, di-sec-butylamino, isobutylamino, di-isobutylamino, di-tert-pentylamino, ethylmethylamino, isopropyl-n-propylamino, or any combination thereof. Examples of the alkylaminos may include, without limitation, one or more of the following: primary alkylaminos, such as, for example and without limitation, methylamino, ethylamino, n-propylamino, isopropylamino, n-butylamino, sec-butylamino, isobutylamino, t-butylamino, pentylamino, 2-aminopentane, 3-aminopentane, 1-amino-2-methylbutane, 2-amino-2-methylbutane, 3-amino-2-methylbutane, 4-amino-2-methylbutane, hexylamino, 5-amino-2-methylpentane, heptylamino, octylamino, nonylamino, decylamino, undecylamino, dodecylamino, tridecylamino, tetradecylamino, pentadecylamino, hexadecylamino, heptadecylamino, and octadecylamino; and secondary alkylaminos, such as, for example and without limitation, dimethylamino, diethylamino, dipropylamino, diisopropylamino, dibutylamino, diisobutylamino, di-sec-butylamino, di-t-butylamino, dipentylamino, dihexylamino, diheptylamino, dioctylamino, dinonylamino, didecylamino, methylethylamino, methylpropylamino, methylisopropylamino, methylbutylamino, methylisobutylamino, methyl-sec-butylamino, methyl-t-butylamino, methylamylamino, methylisoamylamino, ethylpropylamino, ethylisopropylamino, ethylbutylamino, ethylisobutylamino, ethyl-sec-butylamino, ethylamino, ethylisoamylamino, propylbutylamino, and propylisobutylamino.

As used herein, the term “alkoxy” refers to a functional group of formula —OR^{c}, wherein R^{c} is an alkyl (as defined herein), a silylalkyl, a cycloalkyl, or an aryl. In some embodiments, the alkoxy may comprise, consist of, or consist essentially of, or may selected from the group consisting of, at least one of methoxy, ethoxy, methoxy, ethoxy, n-propoxy, 1-methylethoxy (isopropoxy), n-butoxy, iso-butoxy, sec-butoxy, tert-butoxy, or any combination thereof.

As used herein, the term “silyl” refers to a functional group of formula —Si(R^{e}R^{f}R^{g}), where each of R^{e}, R^{f}, and R^{g} is independently a hydrogen or an alkyl, as defined herein. In some embodiments, the silyl is a functional group of formula —SiH₃. In some embodiments, the silyl is a functional group of formula —SiR^{e}H₂, where R^{e} is not hydrogen. In some embodiments, the silyl is a functional group of formula —SiR^{e}R^{f}H, where R^{e} and R^{f} are not hydrogen. In some embodiments, the silyl is a functional group of the formula —Si(R^{e}R^{f}R^{g}), where R^{e}, R^{f}, and R^{g} are not hydrogen. In some embodiments, the silyl is a functional group of formula —Si(CH₃)₃ (e.g., trimethylsilyl).

As used herein, the term “alkoxyalkyl” refers to an alkyl as defined herein, wherein at least one of the hydrogen atoms of the alkyl is replaced with an alkoxy as defined herein. In some embodiments, the term “alkoxyalkyl” refers to a functional group of formula -(alkyl)OR^{a}, wherein the alkyl is defined above and wherein the R^{a} is defined above. In some embodiments, the alkoxyalkyl is a functional group of formula —(CH₂)ₙOR^{a}, where n is 1 to 10 and R^{a} is defined above. In some embodiments, the alkoxyalkyl is a functional group of the formula —CH₂CH₂OCH₃.

As used herein, the term “aralkyl” refers to an alkyl as defined herein, wherein at least one of the hydrogen atoms of the alkyl is replaced with an aryl as defined herein. In some embodiments, the term “aralkyl” refers to a functional group of formula -(alkyl)(aryl), wherein the alkyl is defined herein and the aryl is defined herein. In some embodiments, the aralkyl is —CH₂(C₆H₅).

As used herein, the term “aminoalkyl” refers to an alkyl as defined herein, wherein at least one of the hydrogen atoms of the alkyl is replaced with an amino as defined herein. In some embodiments, the term “aminoalkyl” refers to a functional group of formula -(alkyl)N(R^{a}R^{b}), wherein the alkyl is defined above and wherein R^{a} and R^{b} are defined above. In some embodiments, the aminoalkyl is —CH₂N(CH₃)₂. In some embodiments, the aminoalkyl is —(CH₂)₃N(CH₃)₂. In some embodiments, the aminoalkyl is aminomethyl (—CH₂NH₂). In some embodiments, the aminoalkyl is N,N-dimethylaminoethyl (—CH₂CH₂N(CH₃)₂). In some embodiments, the aminoalkyl is 3-(N-cyclopropylamino)propyl (—CH₂CH₂CH₂NH—Pr).

As used herein, the term “silylalkyl” refers to an alkyl as defined herein, wherein at least one of the hydrogen atoms of the alkyl is replaced with a silyl as defined herein. In some embodiments, the term “silylalkyl” refers to a functional group of formula -(alkyl)Si(R^{e}R^{f}R^{g}), wherein the alkyl is defined above and wherein R^{e}, R^{f}, and R^{g} are defined above. In some embodiments, the silylalky is a functional group of formula —(CH₂)ₘSi(R^{e}R^{f}R^{g}), where m is 1 to 10 and where R^{e}, R^{f}, and R^{g} are defined above. In some embodiments, the silylalkyl is a functional group of formula —CH₂Si(CH₃)₃.

As used herein, the term “haloalkyl” refers to an alkyl as defined here, wherein at least one of the hydrogen atoms of the alkyl is replaced with a halide as defined herein. In some embodiments, the haloalkyl comprises a fluoroalkyl. In some embodiments, the fluoroalkyl comprises at least one of —CH₂CF₃, —CH(CF₃)₂, —CH₂F, —CH₂CH₂F, —CF₃, —CF₂CF₃, or any combination thereof.

As used herein, the term “halide” refers to a —Cl, —Br, —I, or —F.

As used herein, the term “metal” refers to at least one of a alkali metal, an alkaline earth metal, a transition metal, a post-transition metal, or any combination thereof. In some embodiments, the metal comprises a metal cation. In some embodiments, the metal cation comprises a lithium cation, a sodium cation, a potassium cation, a rubidium cation, a cesium cation, a francium cation, a beryllium cation, a magnesium cation, a calcium cation, a strontium cation, a barium cation, a radium cation, a scandium cation, a titanium cation, a vanadium cation, a chromium cation, a manganese cation, an iron cation, a cobalt cation, a nickel cation, a copper cation, a zinc cation, a yttrium cation, a zirconium cation, a niobium cation, a molybdenum cation, a technetium cation, a ruthenium cation, a rhodium cation, a palladium cation, a silver cation, a cadmium cation, a hafnium cation, a tantalum cation, a tungsten cation, a rhenium cation, an osmium cation, an iridium cation, a platinum cation, a gold cation, a mercury cation, an aluminum cation, a gallium cation, an indium cation, tin cation, a thallium cation, a lead cation, a bismuth cation, or a polonium cation. The charge(s) of the metal cations are known and, for simplicity, thus are not repeated here; however, it will be appreciated that the metal cations can have any known charge. For example, in some embodiments, the metal cation comprises Li⁺, Na⁺, K⁺, Rb⁺, Cs⁺, Mg²⁺, Ca²⁺, Sr²⁺, Ba²⁺, or Zn²⁺. In some embodiments, the metal cation is Sn(II) or Sn(IV). In some embodiments, the metal is Ti, Zr, or Hf. In some embodiments, the metal is elemental metal. In some embodiments, the metal comprises, for example and without limitation, a group 1 metal, a group 2 metal, or any combination thereof, among others.

Some embodiments relate to high purity tin compounds and related compositions and related methods. In some embodiments, the compositions are useful in extreme-ultraviolet (EUV) lithography, among other applications, and related methods. The compositions disclosed herein may comprise a highly pure tin (IV) compound, with low levels of impurities, such as, for example and without limitation, at least one of halide impurities, ammonium impurities, or any combination thereof. The methods of synthesis disclosed herein provide a halide-free synthetic route for the preparation of tin (IV) compounds with high yield and high purity, and that is readily scalable. In some embodiments, the methods of synthesis disclosed herein provide a solvent-free method of synthesis, or only use a minimal amount of solvent, thereby providing cost savings, obviating the need for solvent stripping, reducing presence of impurities, among other advantages. The methods employ reagents for the direct conversion to stannic carboxylates. The tin (IV) compounds may be useful for forming tin-containing films useful in the fabrication of microelectronic devices, including semiconductor devices. For example, the compositions may be used as precursors to form tin films. The tin films may be useful in dry resist applications. The tin films may be useful as reflective coatings for extreme-ultraviolet (EUV) lithography, among others.

The tin-containing films may also be formed according to the methods disclosed herein. That is, the tin-containing films disclosed herein may be formed by one or more deposition processes that utilize the precursor compositions. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

Some embodiments relate to a composition. In some embodiments, the composition comprises a precursor useful for manufacturing and/or fabricating microelectronic devices, including, for example and without limitation, semiconductor devices. In some embodiments, the composition comprises a tin (IV) compound. In some embodiments, the tin (IV) compound comprises an anhydrous tin (IV) compound. In some embodiments, the tin (IV) compound comprises an anhydrous tin (IV) alkoxide compound.

In some embodiments, the tin (IV) compound comprises a compound of the formula:

Sn(OR¹)₄,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, the tin (IV) compound comprises a compound of the formula: Sn(OC(CH₃)₃)₄. In some embodiments, the tin (IV) compound comprises an anhydrous compound of the formula: Sn(OC(CH₃)₃)₄.

In some embodiments, the tin (IV) compound comprises a compound of the formula:

Sn(OR¹)ₙ(OR)₄₋ₙ,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
R independently comprises an alkyl; and
n is 0 to 4.

In some embodiments, tin (IV) compound comprises at least one of Sn(O₂CCH₃)₃(O^{t}Bu), Sn(O₂CCH₃)₂(O^{t}Bu)₂, Sn(O₂CCH₃)(O^{t}Bu)₃, or any combination thereof.

In some embodiments, the tin (IV) compound is present in the composition at a purity of at least 95%. In some embodiments, the tin (IV) compound is present in the composition at a purity of at least 96%. In some embodiments, the tin (IV) compound is present in the composition at a purity of at least 97%. In some embodiments, the tin (IV) compound is present in the composition at a purity of at least 98%. In some embodiments, the tin (IV) compound is present in the composition at a purity of at least 99%. In some embodiments, the tin (IV) compound is present in the composition at a purity of at least 99.5%. In some embodiments, the tin (IV) compound is present in the composition at a purity of at least 99.9%. In some embodiments, the tin (IV) compound is present in the composition at a purity of 95% to 100%, or any range or subrange between 95% and 100%. In some embodiments, the tin (IV) compound is present in the composition at a purity of 95% to 96%, 95% to 97%, 95% to 98%, 95% to 99%, 95% to 99.9%, 95% to 99.99%, 95% to 99.999%, 95% to 99.9999%, 96% to 99.9999%, 97% to 99.9999%, 98% to 99.9999%, 99% to 99.9999%, 99.9% to 99.9999%, 99.99% to 99.9999%, 99.999% to 99.9999%, 96% to 100%, 97% to 100%, 98% to 100%, 99% to 100%, 99.9% to 100%, 99.99% to 100%, 99.999% to 100%, or 99.9999% to 100%. In some embodiments, the purity of the tin (IV) compound in the composition is determined by ¹H-NMR. In some embodiments, the purity of the tin (IV) compound in the composition is determined by ¹¹⁹Sn-NMR.

In some embodiments, the composition comprises less than 100 ppb of an impurity as determined by inductively coupled plasma mass spectrometry and/or ion chromatography. In some embodiments, the composition comprises less than 90 ppb, less than 80 ppb, less than 70 ppb, less than 60 ppb, less than 50 ppb, less than 40 ppb, less than 30 ppb, less than 20 ppb, less than 10 ppb, or less than 1 ppb of an impurity as determined by inductively coupled plasma mass spectrometry and/or ion chromatography. In some embodiments, the composition comprises 0.01 ppb to 100 ppb, 0.01 ppb to 90 ppb, 0.01 ppb to 80 ppb, 0.01 ppb to 70 ppb, 0.01 ppb to 60 ppb, 0.01 ppb to 50 ppb, 0.01 ppb to 40 ppb, 0.01 ppb to 30 ppb, 0.01 ppb to 20 ppb, 0.01 ppb to 10 ppb, 0.01 ppb to 9 ppb, 0.01 ppb to 8 ppb, 0.01 ppb to 7 ppb, 0.01 ppb to 6 ppb, 0.01 ppb to 5 ppb, 0.01 ppb to 4 ppb, 0.01 ppb to 3 ppb, 0.01 ppb to 2 ppb, 0.01 ppb to 1 ppb, 0.01 ppb to 0.1 ppb, 0.1 ppb to 100 ppb, 10 ppb to 100 ppb, 20 ppb to 100 ppb, 30 ppb to 100 ppb, 40 ppb to 100 ppb, 50 ppb to 100 ppb, 60 ppb to 100 ppb, 70 ppb to 100 ppb, 80 ppb to 100 ppb, or 90 ppb to 100 ppb of an impurity as determined by inductively coupled plasma mass spectrometry and/or ion chromatography.

In some embodiments, the composition comprises less than 100 ppb of a nitrogen-containing impurity (e.g., amines, ammonium salts, etc.) as determined by inductively coupled plasma mass spectrometry. In some embodiments, the composition comprises less than 90 ppb, less than 80 ppb, less than 70 ppb, less than 60 ppb, less than 50 ppb, less than 40 ppb, less than 30 ppb, less than 20 ppb, less than 10 ppb, or less than 1 ppb of a nitrogen-containing impurity as determined by inductively coupled plasma mass spectrometry. In some embodiments, the composition comprises 0.01 ppb to 100 ppb, 0.01 ppb to 90 ppb, 0.01 ppb to 80 ppb, 0.01 ppb to 70 ppb, 0.01 ppb to 60 ppb, 0.01 ppb to 50 ppb, 0.01 ppb to 40 ppb, 0.01 ppb to 30 ppb, 0.01 ppb to 20 ppb, 0.01 ppb to 10 ppb, 0.01 ppb to 9 ppb, 0.01 ppb to 8 ppb, 0.01 ppb to 7 ppb, 0.01 ppb to 6 ppb, 0.01 ppb to 5 ppb, 0.01 ppb to 4 ppb, 0.01 ppb to 3 ppb, 0.01 ppb to 2 ppb, 0.01 ppb to 1 ppb, 0.01 ppb to 0.1 ppb, 0.1 ppb to 100 ppb, 10 ppb to 100 ppb, 20 ppb to 100 ppb, 30 ppb to 100 ppb, 40 ppb to 100 ppb, 50 ppb to 100 ppb, 60 ppb to 100 ppb, 70 ppb to 100 ppb, 80 ppb to 100 ppb, or 90 ppb to 100 ppb of a nitrogen-containing impurity as determined by inductively coupled plasma mass spectrometry.

In some embodiments, the composition comprises less than 100 ppb of a halide impurity as determined by ion chromatography. In some embodiments, the composition comprises less than 90 ppb, less than 80 ppb, less than 70 ppb, less than 60 ppb, less than 50 ppb, less than 40 ppb, less than 30 ppb, less than 20 ppb, less than 10 ppb, or less than 1 ppb of a halide impurity as determined by ion chromatography. In some embodiments, the composition comprises 0.01 ppb to 100 ppb, 0.01 ppb to 90 ppb, 0.01 ppb to 80 ppb, 0.01 ppb to 70 ppb, 0.01 ppb to 60 ppb, 0.01 ppb to 50 ppb, 0.01 ppb to 40 ppb, 0.01 ppb to 30 ppb, 0.01 ppb to 20 ppb, 0.01 ppb to 10 ppb, 0.01 ppb to 9 ppb, 0.01 ppb to 8 ppb, 0.01 ppb to 7 ppb, 0.01 ppb to 6 ppb, 0.01 ppb to 5 ppb, 0.01 ppb to 4 ppb, 0.01 ppb to 3 ppb, 0.01 ppb to 2 ppb, 0.01 ppb to 1 ppb, 0.01 ppb to 0.1 ppb, 0.1 ppb to 100 ppb, 10 ppb to 100 ppb, 20 ppb to 100 ppb, 30 ppb to 100 ppb, 40 ppb to 100 ppb, 50 ppb to 100 ppb, 60 ppb to 100 ppb, 70 ppb to 100 ppb, 80 ppb to 100 ppb, or 90 ppb to 100 ppb of a halide impurity as determined by ion chromatography.

The impurity may comprise at least one of a halide impurity, a nitrogen-containing-impurity, an ammonium impurity, or any combination thereof. In some embodiments, the halide impurity comprises a halide compound. In some embodiments, the halide compound comprises a compound comprises a Sn—X bond, where X is a halide, such as, for example and without limitation, at least one of —Cl, —Br, —F, —I, or any combination thereof. In some embodiments, the impurity comprises at least SnX₄, where X is independently at least one of —Cl, —Br, —F, —I, or any combination thereof. In some embodiments, the impurity comprises SnCl₄. In some embodiments, the impurity comprises a tin chloride. In some embodiments, the ammonium impurity comprises an ammonium salt. In some embodiments, the ammonium impurity comprises an ammonium halide. In some embodiments, the ammonium impurity comprises an ammonium compound. In some embodiments, the impurity comprises a compound of the formula:

Sn(NR₂)₄₋ₙ(OR¹)ₙ,
where:

n is 1 to 3;

R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, the impurity comprises at least one of Sn(NR₂)₃(OR¹), Sn(NR₂)₂(OR¹)₂, Sn(NR₂)(OR¹)₃, or any combination thereof. In some embodiments, the impurity comprises at least one of an elemental metal, a metal compound, a metal salt, or any combination thereof.

In some embodiments, at least one R and at least one R¹ are different. In some embodiments, at least one R and at least one R¹ are same.

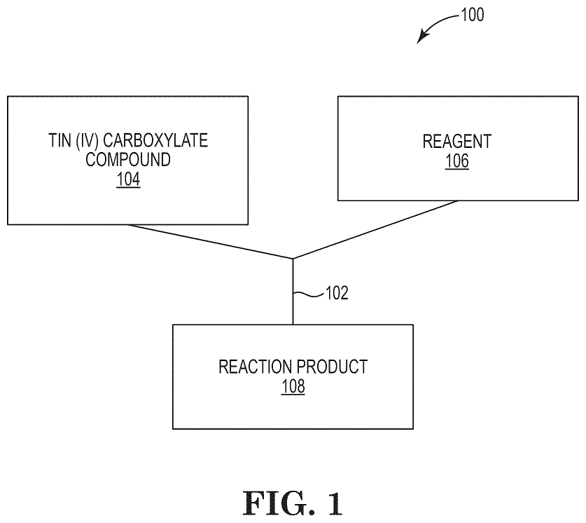

FIG. 1 is a schematic diagram of a flowchart of a method for synthesizing a tin (IV) alkoxide compound, according to some embodiments. As shown in FIG. 1, in some embodiments, the method for synthesizing a tin (IV) alkoxide compound 100 comprises contacting 102 a tin (IV) carboxylate compound 104 with a reagent 106 to form at least one reaction product 108.

In some embodiments, the contacting 102 comprises bringing the tin (IV) carboxylate compound 104 and the reagent 106 into immediate or close proximity. In some embodiments, the contacting 102 comprises bringing the tin (IV) carboxylate compound 104 and the reagent 106 into direct physical contact. In some embodiments, the contacting 102 comprises mixing or stirring the tin (IV) carboxylate compound 104 and the reagent 106. In some embodiments, the contacting 102 comprises agitating the tin (IV) carboxylate compound 104 and the reagent 106. In some embodiments, the contacting 102 comprises reacting the tin (IV) carboxylate compound 104 with the reagent 106. In some embodiments, the contacting 102 comprises adding or combining the tin (IV) carboxylate compound 104 and the reagent 106 to a reaction vessel. In some embodiments, the contacting 102 comprises dissolving at least one of the tin (IV) carboxylate compound 104, the reagent 106, or any combination thereof, in at least one of a solution, a solvent, or a reaction medium. In some embodiments, the contacting 102 comprises dissolving the tin (IV) carboxylate compound 104 in a first solution, dissolving the reagent 106 in a second solution, and combining the first solution and the second solution in a reaction vessel. In some embodiments, the contacting 102 comprises dissolving the tin (IV) carboxylate compound 104 in a first solution, and combining the first solution and the reagent 106 in a reaction vessel. In some embodiments, the contacting 102 comprises dissolving the reagent 106 in a second solution and combining the tin (IV) carboxylate compound 104 and the second solution in a reaction vessel.

In some embodiments, the contacting 102 is performed under heating. In some embodiments, the contacting 102 is performed at a temperature of 30° C. to 200° C., or any range or subrange between 30° C. and 200° C. In some embodiments, for example, the contacting 102 is performed at a temperature of 30° C. to 190° C., 30° C. to 180° C., 30° C. to 170° C., 30° C. to 160° C., 30° C. to 150° C., 30° C. to 140° C., 30° C. to 130° C., 30° C. to 120° C., 30° C. to 110° C., 30° C. to 100° C., 30° C. to 90° C., 30° C. to 80° C., 30° C. to 70° C., 30° C. to 60° C., 30° C. to 50° C., 30° C. to 40° C., 40° C. to 200° C., 50° C. to 200° C., 60° C. to 200° C., 70° C. to 200° C., 80° C. to 200° C., 90° C. to 200° C., 100° C. to 200° C., 110° C. to 200° C., 120° C. to 200° C., 130° C. to 200° C., 140° C. to 200° C., 150° C. to 200° C., 160° C. to 200° C., 170° C. to 200° C., 180° C. to 200° C., or 190° C. to 200° C.

In some embodiments, the contacting 102 is performed in a presence of a solvent. In some embodiments, the solvent comprises an alkane. In some embodiments, the solvent comprises a hexane. In some embodiments, the solvent comprises an ether. In some embodiments, the solvent comprises a diethyl ether. In some embodiments, the solvent comprises a tetrahydrofuran. In some embodiments, the solvent comprises a toluene. In some embodiments, the solvent comprises a benzene. In some embodiments, the solvent comprises a xylene. In some embodiments, the method is performed without any solvent or with minimal solvent.

In some embodiments, at least one equivalent of the reagent 106 is contacted with the tin (IV) carboxylate compound 104. In some embodiments, at least 1, 1.25, 1.5, 1.75, 2, 2.25, 2.5, 2.75, or 3 equivalents of the reagent 106 are contacted with the tin (IV) carboxylate compound 104. In some embodiments, 1 to 10 equivalents, 1 to 9 equivalents, 1 to 8 equivalents, 1 to 7 equivalents, 1 to 6 equivalents, 1 to 5 equivalents, 1 to 4 equivalents, 1 to 3 equivalents, 1 to 2 equivalents, 2 equivalents to 10 equivalents, 3 equivalents to 10 equivalents, 4 equivalents to 10 equivalents, 5 equivalents to 10 equivalents, 6 equivalents to 10 equivalents, 7 equivalents to 10 equivalents, 8 equivalents to 10 equivalents, 9 equivalents to 10 equivalents, or more than 10 equivalents of the reagent 106 are contacted with the tin (IV) carboxylate compound 104.

In some embodiments, the tin (IV) carboxylate compound 104 comprises a compound of the formula:

Sn(O₂CR)₄,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, each R is the same. In some embodiments, at least two R are different. In some embodiments, each R is different.

In some embodiments, the tin (IV) carboxylate compound 104 comprises at least one of Sn(O₂CH)₄, Sn(O₂CCH₃)₄, Sn(O₂CCH₂CH₃)₄, Sn(O₂C(CH₂)₂CH₃)₄, Sn(O₂C(CH₂)₃CH₃)₄, Sn(O₂CCH(CH₃)₂)₄, Sn(O₂CCH₂CH(CH₃)₂)₄, or any combination thereof.

In some embodiments, the reagent 106 comprises a compound of the formula:

MOR¹,
where:
M is an alkali metal cation, an alkaline earth metal cation, a transition metal cation, or a post-transition metal cation;
R¹ comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, the reagent comprises at least one of NaOC(CH₃)₃, KOC(CH₃)₃, LiOC(CH₃)₃, Zn(OC(CH₃)₃)₂, Mg(OC(CH₃)₃)₂, or any combination thereof.

In some embodiments, each R¹ is the same. In some embodiments, at least two R¹s are different. In some embodiments, each R¹ is different.

In some embodiments, R and R¹ are the same. In some embodiments, the R and R¹ are different.

In some embodiments, the at least one reaction product comprises a tin (IV) alkoxide compound. In some embodiments, the tin (IV) alkoxide compound comprises a compound of the formula:

Sn(OR¹)₄,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, each R¹ is the same. In some embodiments, at least two R¹s are different. In some embodiments, each R¹ is different.

In some embodiments, the at least one reaction product 108 is present in the composition at a purity of at least 95%. In some embodiments, the at least one reaction product 108 is present in the composition at a purity of at least 96%. In some embodiments, the at least one reaction product 108 is present in the composition at a purity of at least 97%. In some embodiments, the at least one reaction product 108 is present in the composition at a purity of at least 98%. In some embodiments, the at least one reaction product 108 is present in the composition at a purity of at least 99%. In some embodiments, the at least one reaction product 108 is present in the composition at a purity of at least 99.5%. In some embodiments, the at least one reaction product 108 is present in the composition at a purity of at least 99.9%. In some embodiments, the at least one reaction product 108 is present in the composition at a purity of 95% to 100%, or any range or subrange between 95% and 100%. In some embodiments, the at least one reaction product 108 is present in the composition at a purity of 95% to 96%, 95% to 97%, 95% to 98%, 95% to 99%, 95% to 99.9%, 95% to 99.99%, 95% to 99.999%, 95% to 99.9999%, 96% to 99.9999%, 97% to 99.9999%, 98% to 99.9999%, 99% to 99.9999%, 99.9% to 99.9999%, 99.99% to 99.9999%, 99.999% to 99.9999%, 96% to 100%, 97% to 100%, 98% to 100%, 99% to 100%, 99.9% to 100%, 99.99% to 100%, 99.999% to 100%, or 99.9999% to 100%. In some embodiments, the purity of the at least one reaction product 108 in the composition is determined by ¹H-NMR. In some embodiments, the purity of the at least one reaction product 108 in the composition is determined by ¹¹⁹Sn-NMR.

In some embodiments, the composition comprises less than 100 ppb of an impurity as determined by inductively coupled plasma mass spectrometry and/or ion chromatography. In some embodiments, the composition comprises less than 90 ppb, less than 80 ppb, less than 70 ppb, less than 60 ppb, less than 50 ppb, less than 40 ppb, less than 30 ppb, less than 20 ppb, less than 10 ppb, or less than 1 ppb of an impurity as determined by inductively coupled plasma mass spectrometry and/or ion chromatography. In some embodiments, the composition comprises 0.01 ppb to 100 ppb, 0.01 ppb to 90 ppb, 0.01 ppb to 80 ppb, 0.01 ppb to 70 ppb, 0.01 ppb to 60 ppb, 0.01 ppb to 50 ppb, 0.01 ppb to 40 ppb, 0.01 ppb to 30 ppb, 0.01 ppb to 20 ppb, 0.01 ppb to 10 ppb, 0.01 ppb to 9 ppb, 0.01 ppb to 8 ppb, 0.01 ppb to 7 ppb, 0.01 ppb to 6 ppb, 0.01 ppb to 5 ppb, 0.01 ppb to 4 ppb, 0.01 ppb to 3 ppb, 0.01 ppb to 2 ppb, 0.01 ppb to 1 ppb, 0.01 ppb to 0.1 ppb, 0.1 ppb to 100 ppb, 10 ppb to 100 ppb, 20 ppb to 100 ppb, 30 ppb to 100 ppb, 40 ppb to 100 ppb, 50 ppb to 100 ppb, 60 ppb to 100 ppb, 70 ppb to 100 ppb, 80 ppb to 100 ppb, or 90 ppb to 100 ppb of an impurity as determined by inductively coupled plasma mass spectrometry and/or ion chromatography.

In some embodiments, the composition comprises less than 100 ppb of a nitrogen-containing impurity as determined by inductively coupled plasma mass spectrometry. In some embodiments, the composition comprises less than 90 ppb, less than 80 ppb, less than 70 ppb, less than 60 ppb, less than 50 ppb, less than 40 ppb, less than 30 ppb, less than 20 ppb, less than 10 ppb, or less than 1 ppb of a nitrogen-containing impurity as determined by inductively coupled plasma mass spectrometry. In some embodiments, the composition comprises 0.01 ppb to 100 ppb, 0.01 ppb to 90 ppb, 0.01 ppb to 80 ppb, 0.01 ppb to 70 ppb, 0.01 ppb to 60 ppb, 0.01 ppb to 50 ppb, 0.01 ppb to 40 ppb, 0.01 ppb to 30 ppb, 0.01 ppb to 20 ppb, 0.01 ppb to 10 ppb, 0.01 ppb to 9 ppb, 0.01 ppb to 8 ppb, 0.01 ppb to 7 ppb, 0.01 ppb to 6 ppb, 0.01 ppb to 5 ppb, 0.01 ppb to 4 ppb, 0.01 ppb to 3 ppb, 0.01 ppb to 2 ppb, 0.01 ppb to 1 ppb, 0.01 ppb to 0.1 ppb, 0.1 ppb to 100 ppb, 10 ppb to 100 ppb, 20 ppb to 100 ppb, 30 ppb to 100 ppb, 40 ppb to 100 ppb, 50 ppb to 100 ppb, 60 ppb to 100 ppb, 70 ppb to 100 ppb, 80 ppb to 100 ppb, or 90 ppb to 100 ppb of a nitrogen-containing impurity as determined by inductively coupled plasma mass spectrometry.

In some embodiments, the composition comprises less than 100 ppb of a halide impurity as determined by ion chromatography. In some embodiments, the composition comprises less than 90 ppb, less than 80 ppb, less than 70 ppb, less than 60 ppb, less than 50 ppb, less than 40 ppb, less than 30 ppb, less than 20 ppb, less than 10 ppb, or less than 1 ppb of a halide impurity as determined by ion chromatography. In some embodiments, the composition comprises 0.01 ppb to 100 ppb, 0.01 ppb to 90 ppb, 0.01 ppb to 80 ppb, 0.01 ppb to 70 ppb, 0.01 ppb to 60 ppb, 0.01 ppb to 50 ppb, 0.01 ppb to 40 ppb, 0.01 ppb to 30 ppb, 0.01 ppb to 20 ppb, 0.01 ppb to 10 ppb, 0.01 ppb to 9 ppb, 0.01 ppb to 8 ppb, 0.01 ppb to 7 ppb, 0.01 ppb to 6 ppb, 0.01 ppb to 5 ppb, 0.01 ppb to 4 ppb, 0.01 ppb to 3 ppb, 0.01 ppb to 2 ppb, 0.01 ppb to 1 ppb, 0.01 ppb to 0.1 ppb, 0.1 ppb to 100 ppb, 10 ppb to 100 ppb, 20 ppb to 100 ppb, 30 ppb to 100 ppb, 40 ppb to 100 ppb, 50 ppb to 100 ppb, 60 ppb to 100 ppb, 70 ppb to 100 ppb, 80 ppb to 100 ppb, or 90 ppb to 100 ppb of a halide impurity as determined by ion chromatography.

The impurity may comprise at least one of a halide impurity, a nitrogen-containing impurity, an ammonium impurity, or any combination thereof. In some embodiments, the halide impurity comprises a halide compound. In some embodiments, the halide compound comprises a compound comprises a Sn—X bond, where X is a halide, such as, for example and without limitation, at least one of —Cl, —Br, —F, —I, or any combination thereof. In some embodiments, the impurity comprises at least SnX₄, where X is independently at least one of —Cl, —Br, —F, —I, or any combination thereof. In some embodiments, the impurity comprises SnCl₄. In some embodiments, the impurity comprises a tin chloride. In some embodiments, the ammonium impurity comprises an ammonium salt. In some embodiments, the ammonium impurity comprises an ammonium halide. In some embodiments, the ammonium impurity comprises an ammonium compound. In some embodiments, the impurity comprises a compound of the formula:

Sn(NR₂)₄₋ₙ(OR¹)ₙ,
where:
n is 1 to 3;
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, at least one R and at least one R¹ are different. In some embodiments, at least one R and at least one R¹ are same

In some embodiments, the impurity comprises at least one of Sn(NR₂)₃(OR¹), Sn(NR₂)₂(OR¹)₂, Sn(NR₂)(OR¹)₃, or any combination thereof. In some embodiments, the impurity comprises at least one of an elemental metal, a metal compound, a metal salt, or any combination thereof.

Although not shown in FIG. 1, in some embodiments, the method for synthesizing a tin (IV) alkoxide compound 100 comprises, prior to contacting 102, obtaining the tin (IV) carboxylate compound.

In some embodiments, the tin (IV) carboxylate compound is obtained by contacting a tin metal with a carboxylate compound to obtain the tin (IV) carboxylate compound. The contacting can be conducted similar to the contacting 102 and thus is not repeated here for simplicity.

In some embodiments, the tin metal comprises Sn. In some embodiments, the tin metal comprises elemental Sn, a Sn cation, a Sn-containing molecule, or any combination thereof.

In some embodiments, the carboxylate compound comprises a compound of the formula:

RCO₂H,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, the tin (IV) carboxylate compound is obtained by contacting a tin oxide compound with a carboxylate compound to obtain the tin (IV) carboxylate compound. The contacting can be conducted similar to the contacting 102 and thus is not repeated here for simplicity.

In some embodiments, the tin oxide compound comprises a compound of the formula: SnO.

In some embodiments, the carboxylate compound comprises a compound of the formula:

RCO₂H,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, the tin (IV) carboxylate compound is obtained by contacting a tin oxide compound with a carboxylate compound to obtain the tin (IV) carboxylate compound. The contacting can be conducted similar to the contacting 102 and thus is not repeated here for simplicity.

In some embodiments, the tin oxide compound comprises a compound of the formula: SnO₂.

In some embodiments, the carboxylate compound comprises a compound of the formula:

RCO₂H,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, the tin (IV) carboxylate compound is obtained by contacting a tin compound with a carboxylate compound to obtain the tin (IV) carboxylate compound. The contacting can be conducted similar to the contacting 102 and thus is not repeated here for simplicity.

In some embodiments, the tin compound comprises a compound of the formula:

Sn(R′)₄,
where:
R′ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, the carboxylate compound comprises a compound of the formula:

RCO₂H,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, R′ comprises at least one of an alkenyl, an aryl, or any combination thereof. In some embodiments, R′ comprises at least one of a vinyl, a phenyl, a benzyl, a benzoyl, or any combination thereof. In some embodiments, R′ is substituted with at least one alkyl.

In some embodiments, the tin compound comprises at least one of a tetraalkyl tin, a tetraalkenyl tin, a tetraaryl tin, or any combination thereof. In some embodiments, for example, the tin compound comprises at least one of tetraphenyl tin, tetravinyl tin, or any combination thereof.

In some embodiments, each R′ is different. In some embodiments, at least two R′ are different. In some embodiments, each R′ is the same.

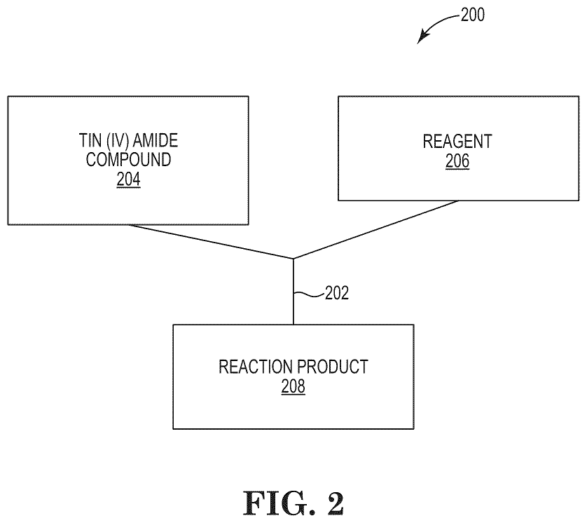

FIG. 2 is a schematic diagram of a flowchart of a method for synthesizing a tin (IV) alkoxide compound, according to some embodiments. As shown in FIG. 2, in some embodiments, the method for synthesizing a tin (IV) alkoxide compound 200 comprises contacting 202 a tin (IV) amide compound 204 with a reagent 206 to form at least one reaction product 208.

In some embodiments, the contacting 202 comprises bringing the tin (IV) amide compound 204 and the reagent 206 into immediate or close proximity. In some embodiments, the contacting 202 comprises bringing the tin (IV) amide compound 204 and the reagent 206 into direct physical contact. In some embodiments, the contacting 202 comprises mixing or stirring the tin (IV) amide compound 204 and the reagent 206. In some embodiments, the contacting 202 comprises agitating the tin (IV) amide compound 204 and the reagent 206. In some embodiments, the contacting 202 comprises reacting the tin (IV) amide compound 204 with the reagent 206. In some embodiments, the contacting 202 comprises adding or combining the tin (IV) amide compound 204 and the reagent 206 to a reaction vessel. In some embodiments, the contacting 202 comprises dissolving at least one of the tin (IV) amide compound 204, the reagent 206, or any combination thereof, in at least one of a solution, a solvent, or a reaction medium. In some embodiments, the contacting 202 comprises dissolving the tin (IV) amide compound 204 in a first solution, dissolving the reagent 206 in a second solution, and combining the first solution and the second solution in a reaction vessel. In some embodiments, the contacting 202 comprises dissolving the tin (IV) amide compound 204 in a first solution, and combining the first solution and the reagent 206 in a reaction vessel. In some embodiments, the contacting 202 comprises dissolving the reagent 206 in a second solution and combining the tin (IV) amide compound 204 and the second solution in a reaction vessel.

In some embodiments, the contacting 202 is performed under heating. In some embodiments, the contacting 202 is performed at a temperature of 30° C. to 200° C., or any range or subrange between 30° C. and 200° C. In some embodiments, for example, the contacting 202 is performed at a temperature of 30° C. to 190° C., 30° C. to 180° C., 30° C. to 170° C., 30° C. to 160° C., 30° C. to 150° C., 30° C. to 140° C., 30° C. to 130° C., 30° C. to 120° C., 30° C. to 110° C., 30° C. to 100° C., 30° C. to 90° C., 30° C. to 80° C., 30° C. to 70° C., 30° C. to 60° C., 30° C. to 50° C., 30° C. to 40° C., 40° C. to 200° C., 50° C. to 200° C., 60° C. to 200° C., 70° C. to 200° C., 80° C. to 200° C., 90° C. to 200° C., 100° C. to 200° C., 110° C. to 200° C., 120° C. to 200° C., 130° C. to 200° C., 140° C. to 200° C., 150° C. to 200° C., 160° C. to 200° C., 170° C. to 200° C., 180° C. to 200° C., or 190° C. to 200° C.

In some embodiments, the contacting 202 is performed in a presence of a solvent. In some embodiments, the solvent comprises an alkane. In some embodiments, the solvent comprises a hexane. In some embodiments, the solvent comprises an ether. In some embodiments, the solvent comprises a diethyl ether. In some embodiments, the solvent comprises a tetrahydrofuran. In some embodiments, the solvent comprises a toluene. In some embodiments, the solvent comprises a benzene. In some embodiments, the solvent comprises a xylene.

In some embodiments, at least one equivalent of the reagent 206 is contacted with the tin (IV) amide compound 204. In some embodiments, at least 1, 1.25, 1.5, 1.75, 2, 2.25, 2.5, 2.75, or 3 equivalents of the reagent 206 are contacted with the tin (IV) amide compound 204. In some embodiments, 1 to 10 equivalents, 1 to 9 equivalents, 1 to 8 equivalents, 1 to 7 equivalents, 1 to 6 equivalents, 1 to 5 equivalents, 1 to 4 equivalents, 1 to 3 equivalents, 1 to 2 equivalents, 2 equivalents to 10 equivalents, 3 equivalents to 10 equivalents, 4 equivalents to 10 equivalents, 5 equivalents to 10 equivalents, 6 equivalents to 10 equivalents, 7 equivalents to 10 equivalents, 8 equivalents to 10 equivalents, 9 equivalents to 10 equivalents, or more than 10 equivalents of the reagent 206 are contacted with the tin (IV) amide compound 204.

In some embodiments, the tin (IV) amide compound 204 comprises a compound of the formula:

Sn(NR₂)₄,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, each R is the same. In some embodiments, at least two R are different. In some embodiments, each R is different.

In some embodiments, the tin (IV) amide compound 204 comprises Sn(N(CH₃)₂)₄.

In some embodiments, the reagent 206 comprises a compound of the formula:

HOR¹,
where:
R¹ comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, each R¹ is the same. In some embodiments, at least two R¹s are different. In some embodiments, each R¹ is different.

In some embodiments, R and R¹ are the same. In some embodiments, the R and R¹ are different.

In some embodiments, the reagent 206 comprises HOC(CH₃)₃.

In some embodiments, the at least one reaction product 208 comprises a tin (IV) alkoxide compound. In some embodiments, the tin (IV) alkoxide compound comprises a compound of the formula:

Sn(OR¹)₄,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, each R¹ is the same. In some embodiments, at least two R¹s are different. In some embodiments, each R¹ is different.

In some embodiments, when three equivalents or less of the reagent 206 is contacted with the tin (IV) amide compound 204, the method 200 further comprises forming a compound of the formula:

Sn(NR₂)₄₋ₙ(OR¹)ₙ,
where:
n is 1 to 3;
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, for example, the method 200 further comprises forming a compound of the formula:

Sn(NR₂)₃(OR¹),
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, at least one R and at least one R¹ are different. In some embodiments, at least one R and at least one R¹ are same.

In some embodiments, the method 200 further comprises forming a compound of the formula:

Sn(NR₂)₂(OR¹)₂,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, at least one R and at least one R¹ are different. In some embodiments, at least one R and at least one R¹ are same.

In some embodiments, the method 200 further comprises forming a compound of the formula:

Sn(NR₂)(OR¹)₃,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, at least one R and at least one R¹ are different. In some embodiments, at least one R and at least one R¹ are same.

In some embodiments, when more than three equivalents of the reagent 206 is contacted with the tin (IV) amide compound 204, the method 200 does not comprise forming the compound of the formula, or the method 200 comprises forming negligible amounts of the compound of the formula:

Sn(NR₂)₄₋ₙ(OR¹)ₙ,
where:
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, at least one R and at least one R¹ are different. In some embodiments, at least one R and at least one R¹ are same.

In some embodiments, the at least one reaction product 208 is present in the composition at a purity of at least 95%. In some embodiments, the at least one reaction product 208 is present in the composition at a purity of at least 96%. In some embodiments, the at least one reaction product 208 is present in the composition at a purity of at least 97%. In some embodiments, the at least one reaction product 208 is present in the composition at a purity of at least 98%. In some embodiments, the at least one reaction product 208 is present in the composition at a purity of at least 99%. In some embodiments, the at least one reaction product 208 is present in the composition at a purity of at least 99.5%. In some embodiments, the at least one reaction product 208 is present in the composition at a purity of at least 99.9%. In some embodiments, the at least one reaction product 208 is present in the composition at a purity of 95% to 100%, or any range or subrange between 95% and 100%. In some embodiments, the at least one reaction product 208 is present in the composition at a purity of 95% to 96%, 95% to 97%, 95% to 98%, 95% to 99%, 95% to 99.9%, 95% to 99.99%, 95% to 99.999%, 95% to 99.9999%, 96% to 99.9999%, 97% to 99.9999%, 98% to 99.9999%, 99% to 99.9999%, 99.9% to 99.9999%, 99.99% to 99.9999%, 99.999% to 99.9999%, 96% to 100%, 97% to 100%, 98% to 100%, 99% to 100%, 99.9% to 100%, 99.99% to 100%, 99.999% to 100%, or 99.9999% to 100%. In some embodiments, the purity of the at least one reaction product 208 in the composition is determined by ¹H-NMR. In some embodiments, the purity of the at least one reaction product 208 in the composition is determined by ¹¹⁹Sn-NMR.

In some embodiments, the composition comprises less than 100 ppb of an impurity as determined by inductively coupled plasma mass spectrometry and/or ion chromatography. In some embodiments, the composition comprises less than 90 ppb, less than 80 ppb, less than 70 ppb, less than 60 ppb, less than 50 ppb, less than 40 ppb, less than 30 ppb, less than 20 ppb, less than 10 ppb, or less than 1 ppb of an impurity as determined by inductively coupled plasma mass spectrometry and/or ion chromatography. In some embodiments, the composition comprises 0.01 ppb to 100 ppb, 0.01 ppb to 90 ppb, 0.01 ppb to 80 ppb, 0.01 ppb to 70 ppb, 0.01 ppb to 60 ppb, 0.01 ppb to 50 ppb, 0.01 ppb to 40 ppb, 0.01 ppb to 30 ppb, 0.01 ppb to 20 ppb, 0.01 ppb to 10 ppb, 0.01 ppb to 9 ppb, 0.01 ppb to 8 ppb, 0.01 ppb to 7 ppb, 0.01 ppb to 6 ppb, 0.01 ppb to 5 ppb, 0.01 ppb to 4 ppb, 0.01 ppb to 3 ppb, 0.01 ppb to 2 ppb, 0.01 ppb to 1 ppb, 0.01 ppb to 0.1 ppb, 0.1 ppb to 100 ppb, 10 ppb to 100 ppb, 20 ppb to 100 ppb, 30 ppb to 100 ppb, 40 ppb to 100 ppb, 50 ppb to 100 ppb, 60 ppb to 100 ppb, 70 ppb to 100 ppb, 80 ppb to 100 ppb, or 90 ppb to 100 ppb of an impurity as determined by inductively coupled plasma mass spectrometry and/or ion chromatography.

In some embodiments, the composition comprises less than 100 ppb of a nitrogen-containing impurity as determined by inductively coupled plasma mass spectrometry. In some embodiments, the composition comprises less than 90 ppb, less than 80 ppb, less than 70 ppb, less than 60 ppb, less than 50 ppb, less than 40 ppb, less than 30 ppb, less than 20 ppb, less than 10 ppb, or less than 1 ppb of a nitrogen-containing impurity as determined by inductively coupled plasma mass spectrometry. In some embodiments, the composition comprises 0.01 ppb to 100 ppb, 0.01 ppb to 90 ppb, 0.01 ppb to 80 ppb, 0.01 ppb to 70 ppb, 0.01 ppb to 60 ppb, 0.01 ppb to 50 ppb, 0.01 ppb to 40 ppb, 0.01 ppb to 30 ppb, 0.01 ppb to 20 ppb, 0.01 ppb to 10 ppb, 0.01 ppb to 9 ppb, 0.01 ppb to 8 ppb, 0.01 ppb to 7 ppb, 0.01 ppb to 6 ppb, 0.01 ppb to 5 ppb, 0.01 ppb to 4 ppb, 0.01 ppb to 3 ppb, 0.01 ppb to 2 ppb, 0.01 ppb to 1 ppb, 0.01 ppb to 0.1 ppb, 0.1 ppb to 100 ppb, 10 ppb to 100 ppb, 20 ppb to 100 ppb, 30 ppb to 100 ppb, 40 ppb to 100 ppb, 50 ppb to 100 ppb, 60 ppb to 100 ppb, 70 ppb to 100 ppb, 80 ppb to 100 ppb, or 90 ppb to 100 ppb of a nitrogen-containing impurity as determined by inductively coupled plasma mass spectrometry.

In some embodiments, the composition comprises less than 100 ppb of a halide impurity as determined by ion chromatography. In some embodiments, the composition comprises less than 90 ppb, less than 80 ppb, less than 70 ppb, less than 60 ppb, less than 50 ppb, less than 40 ppb, less than 30 ppb, less than 20 ppb, less than 10 ppb, or less than 1 ppb of a halide impurity as determined by ion chromatography. In some embodiments, the composition comprises 0.01 ppb to 100 ppb, 0.01 ppb to 90 ppb, 0.01 ppb to 80 ppb, 0.01 ppb to 70 ppb, 0.01 ppb to 60 ppb, 0.01 ppb to 50 ppb, 0.01 ppb to 40 ppb, 0.01 ppb to 30 ppb, 0.01 ppb to 20 ppb, 0.01 ppb to 10 ppb, 0.01 ppb to 9 ppb, 0.01 ppb to 8 ppb, 0.01 ppb to 7 ppb, 0.01 ppb to 6 ppb, 0.01 ppb to 5 ppb, 0.01 ppb to 4 ppb, 0.01 ppb to 3 ppb, 0.01 ppb to 2 ppb, 0.01 ppb to 1 ppb, 0.01 ppb to 0.1 ppb, 0.1 ppb to 100 ppb, 10 ppb to 100 ppb, 20 ppb to 100 ppb, 30 ppb to 100 ppb, 40 ppb to 100 ppb, 50 ppb to 100 ppb, 60 ppb to 100 ppb, 70 ppb to 100 ppb, 80 ppb to 100 ppb, or 90 ppb to 100 ppb of a halide impurity as determined by ion chromatography.

The impurity may comprise at least one of a halide impurity, a nitrogen-containing impurity, an ammonium impurity, or any combination thereof. In some embodiments, the halide impurity comprises a halide compound. In some embodiments, the halide compound comprises a compound comprises a Sn—X bond, where X is a halide, such as, for example and without limitation, at least one of —Cl, —Br, —F, —I, or any combination thereof. In some embodiments, the impurity comprises at least SnX₄, where X is independently at least one of —Cl, —Br, —F, —I, or any combination thereof. In some embodiments, the impurity comprises SnCl₄. In some embodiments, the impurity comprises a tin chloride. In some embodiments, the ammonium impurity comprises an ammonium salt. In some embodiments, the ammonium impurity comprises an ammonium halide. In some embodiments, the ammonium impurity comprises an ammonium compound. In some embodiments, the impurity comprises a compound of the formula:

Sn(NR₂)₄₋ₙ(OR¹)ₙ,
where:
n is 1 to 3;
R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

In some embodiments, at least one R and at least one R¹ are different. In some embodiments, at least one R and at least one R¹ are same.

In some embodiments, the impurity comprises at least one of Sn(NR₂)₃(OR¹), Sn(NR₂)₂(OR¹)₂, Sn(NR₂)(OR¹)₃, or any combination thereof. In some embodiments, the impurity comprises at least one of an elemental metal, a metal compound, a metal salt, or any combination thereof.

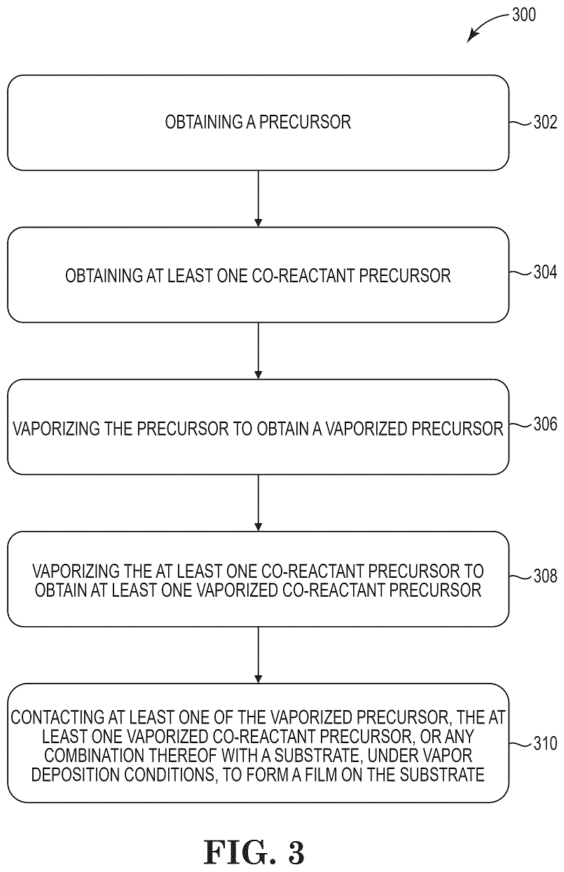

FIG. 3 is a flowchart of a method for forming a film 300, according to some embodiments. As shown in FIG. 3, the method for forming a film 300 may comprise, consist of, or consist essentially of one or more of the following steps: obtaining 302 a precursor, obtaining 304 at least one co-reactant precursor, vaporizing 306 the precursor to obtain a vaporized precursor, vaporizing 308 the at least one co-reactant precursor to obtain at least one vaporized co-reactant precursor, contacting 310 at least one of the vaporized precursor, the at least one vaporized co-reactant precursor, or any combination thereof with a substrate, under vapor deposition conditions, to form a tin-containing film on the substrate.

The step 302 may comprise, consist of, or consist essentially of obtaining a precursor. The precursor may comprise, consist of, or consist essentially of any one or more of the compositions comprising the compositions disclosed herein, including, for example and without limitation, any one or more of the compositions produced according to any one or more of the methods disclosed herein, the reaction products produced according to any one or more of the methods disclosed herein, and the like. The obtaining may comprise obtaining a container or other vessel comprising the precursor. In some embodiments, the precursor may be obtained in a container or other vessel in which the precursor is to be vaporized.

The step 304 may comprise, consist of, or consist essentially of obtaining at least one co-reactant precursor. In some embodiments, the at least one co-reactant precursor comprises, consists of, or consists essentially of, or is selected from the group consisting of, at least one of an oxidizing gas, a reducing gas, a hydrocarbon, or any combination thereof. The at least one co-reactant precursor may be selected to obtain a desired tin-containing film. In some embodiments, the at least one co-reactant precursor may comprise, consist of, or consist essentially of at least one of N₂, H₂, NH₃, N₂H₄, CH₃HNNH₂, CH₃HNNHCH₃, NCH₃H₂, NCH₃CH₂H₂, N(CH₃)₂H, N(CH₃CH₂)₂H, N(CH₃)₃, N(CH₃CH₂)₃, Si(CH₃)₂NH, pyrazoline, pyridine, ethylene diamine, or any combination thereof. In some embodiments, the at least one co-reactant precursor may comprise, consist of, or consist essentially of at least one of H₂, O₂, O₃, H₂O, H₂O₂, NO, N₂O, NO₂, CO, CO₂, a carboxylic acid, an alcohol, a diol, or any combination thereof. In some embodiments, the at least one co-reactant precursor comprise, consist of, or consist essentially of at least one of methane, ethane, ethylene, acetylene, or any combination thereof. The obtaining may comprise obtaining a container or other vessel comprising the at least one co-reactant precursor. In some embodiments, the at least one co-reactant precursor may be obtained in a container or other vessel in which the at least one co-reactant precursor is to be vaporized. In some embodiments, the method further comprises an inert gas, such as, for example, at least one of argon, helium, nitrogen, or any combination thereof.

The step 306 may comprise, consist of, or consist essentially of vaporizing the precursor to obtain a vaporized precursor. The vaporizing may comprise, consist of, or consist essentially of heating the precursor sufficient to obtain the vaporized precursor. In some embodiments, the vaporizing may comprise, consist of, or consist essentially of heating a container comprising the precursor. In some embodiments, the vaporizing may comprise, consist of, or consist essentially of heating the precursor in a deposition chamber in which the vapor deposition process is performed. In some embodiments, the vaporizing may comprise, consist of, or consist essentially of heating a conduit for delivering the precursor, vaporized precursor, or any combination thereof to, for example, a deposition chamber. In some embodiments, the vaporizing may comprise, consist of, or consist essentially of operating a vapor delivery system comprising the precursor. In some embodiments, the vaporizing may comprise, consist of, or consist essentially of heating to a temperature sufficient to vaporize the precursor to obtain the vaporized precursor. In some embodiments, the vaporizing may comprise, consist of, or consist essentially of heating to a temperature below a decomposition temperature of at least one of the precursor, the vaporized precursor, or any combination thereof. In some embodiments, the precursor may be present in a gas phase, in which case the step 306 is optional and not required. For example, the precursor may comprise, consist of, or consist essentially of the vaporized precursor.

The step 308 may comprise, consist of, or consist essentially of vaporizing the at least one co-reactant precursor to obtain the at least one vaporized co-reactant precursor. In some embodiments, the vaporizing may comprise, consist of, or consist essentially of heating the at least one co-reactant precursor sufficient to obtain the at least one vaporized co-reactant precursor. In some embodiments, the vaporizing may comprise, consist of, or consist essentially of heating a container comprising the at least one co-reactant precursor. In some embodiments, the vaporizing may comprise, consist of, or consist essentially of heating the at least one co-reactant precursor in a deposition chamber in which the vapor deposition process is performed. In some embodiments, the vaporizing may comprise, consist of, or consist essentially of heating a conduit for delivering the at least one co-reactant precursor, the at least one vaporized co-reactant precursor, or any combination thereof to, for example, a deposition chamber. In some embodiments, the vaporizing may comprise, consist of, or consist essentially of operating a vapor delivery system comprising the at least one co-reactant precursor. In some embodiments, the vaporizing may comprise, consist of, or consist essentially of heating to a temperature sufficient to vaporize the at least one co-reactant precursor to obtain the at least one vaporized co-reactant precursor. In some embodiments, the vaporizing may comprise, consist of, or consist essentially of heating to a temperature below a decomposition temperature of at least one of the at least one co-reactant precursor, the at least one vaporized co-reactant precursor, or any combination thereof. In some embodiments, the at least one co-reactant precursor may be present in a gas phase, in which case the step 308 is optional and not required. For example, the at least one co-reactant precursor may comprise, consist of, or consist essentially of the at least one vaporized co-reactant precursor.

The step 310 may comprise, consist of, or consist essentially of contacting at least one of the vaporized precursor, the at least one vaporized co-reactant precursor, or any combination thereof, with the substrate, under vapor deposition conditions, sufficient to form a tin-containing film on a surface of the substrate. The contacting may be performed in any system, apparatus, device, assembly, chamber thereof, or component thereof suitable for vapor deposition processes, including, for example and without limitation, a deposition chamber, among others. The vaporized precursor and the at least one co-reactant precursor may be contacted with the substrate at the same time or at different times. For example, each of the vaporized precursor, the at least one vaporized co-reactant precursor, and the substrate may be present in the deposition chamber at the same time. That is, in some embodiments, the contacting may comprise contemporaneous contacting or simultaneous contacting of the vaporized precursor and the at least one vaporized co-reactant precursor with the substrate. Alternatively, each of the vaporized precursor and the at least one vaporized co-reactant precursor may be present in the deposition chamber at different times. That is, in some embodiments, the contacting may comprise alternate and/or sequential contacting, in one or more cycles, of the vaporized precursor with the substrate and subsequently contacting the at least one vaporized co-reactant precursor with the substrate.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise, consist of, or consist essentially of a deposition temperature. The deposition temperature may be a temperature less than the thermal decomposition temperature of at least one of the vaporized precursor, the at least one vaporized co-reactant precursor, or any combination thereof. The deposition temperature may be sufficiently high to reduce or avoid condensation of at least one of the vaporized precursor, the at least one vaporized co-reactant precursor, or any combination thereof. In some embodiments, the substrate may be heated to the deposition temperature. In some embodiments, the chamber or other vessel in which the substrate is contacted with the vaporized precursor and the at least one vaporized co-reactant precursor is heated to the deposition temperature. In some embodiments, at least one of the vaporized precursor, the at least one vaporized co-reactant precursor, or any combination thereof may be heated to the deposition temperature.

The deposition temperature may be a temperature of 200° C. to 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500°° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The vapor deposition conditions may comprise, consist of, or consist essentially of a deposition pressure. In some embodiments, the deposition pressure may comprise, consist of, or consist essentially of a vapor pressure of at least one of the vaporized precursor, the at least one vaporized co-reactant precursor, or any combination thereof. In some embodiments, the deposition pressure may comprise, consist of, or consist essentially of a chamber pressure.

The deposition pressure may be a pressure of 0.001 Torr to 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

The substrate may comprise, consist of, or consist essentially of at least one of Si, Co, Cu, Al, W, WN, WC, TiN, Mo, MoC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof.

The tin-containing film may comprise a tin oxide or a tin oxide film. In some embodiments, the tin-containing film comprises a functionalized tin oxide. In some embodiments, the tin-containing film comprises a functionalized tin oxide of the formula: RSnO_{z}, where z is 1 to 6. In some embodiments, R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, an ether, an amine, a halide, an imide, a cyanate, a nitrile, an alkoxide, a cyclopentadienyl, or an indenyl.

Some embodiments relate to a tin-containing film on a surface of a substrate. In some embodiments, the tin-containing film comprises any film formed according to the methods disclosed herein. In some embodiments, the tin-containing film comprises any film prepared from the precursors disclosed herein.

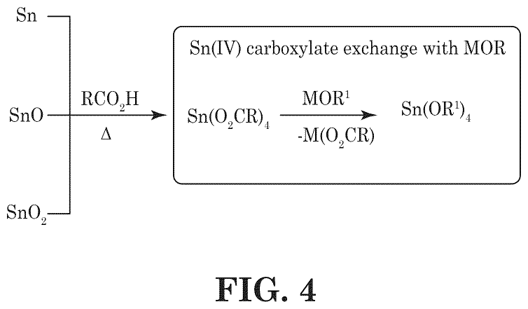

FIG. 4 depicts a reaction scheme of a method for synthesizing a tin (IV) alkoxide compound, according to some embodiments. As shown in FIG. 4, the synthesis can involve reacting at least one of Sn, SnO, SnO₂, or any combination thereof, with a carboxylate compound under heat to obtain a tin (IV) carboxylate compound. The resulting tin (IV) carboxylate compound can be reacted with a metal alkoxide to obtain the tin (IV) alkoxide compound.

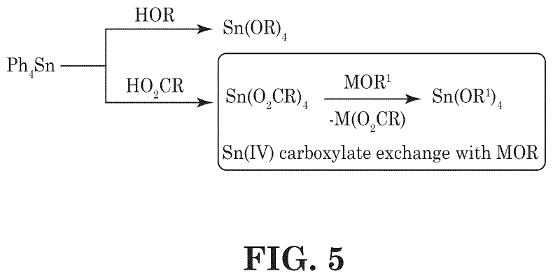

FIG. 5 depicts a reaction scheme of a method for synthesizing a tin (IV) alkoxide compound, according to some embodiments. As shown in FIG. 5, the synthesis can involve reacting, for example, a tetraphenyl tin compound with a carboxylate compound to obtain a tin (IV) carboxylate compound. The resulting tin (IV) carboxylate compound can be reacted with a metal alkoxide to obtain the tin (IV) alkoxide compound.

### EXAMPLE 1

### Synthesis of Sn(O^{t}Bu)₄

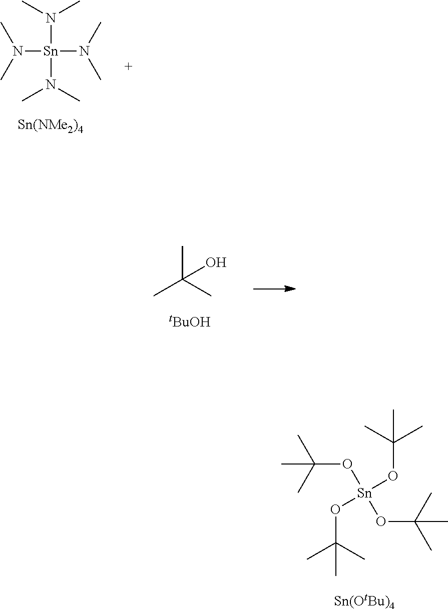

A 12 L 4-neck reaction pot outfitted with an overhead stirrer, thermocouple, reflux condenser, and gas inlet adapter was placed on a Schlenk line and flushed with N₂ gas over a period of 12 hours. In a nitrogen-filled glovebox, Sn(NMe₂)₄ (2.00 KG, 6.78 mol) was placed in a 4-neck 5L flask and diluted with hexanes (2 L) to form a yellow solution which was removed from the glovebox and similarly placed on the Schlenk line under N2.The two flasks were connected via ⅜″ PTFE tubing and the amide solution was transferred to a 12 L flask using pressure differential. In the nitrogen-filled glovebox, ^{t}BuOH (2.060 KG, 27.79 mol) was placed in a 4-neck 5 L flask equipped with a magnetic stir bar and dissolved in hexanes (4 L), causing an endotherm and requiring 30 minutes of stirring to fully dissolve all of the alcohol. The ^{t}BuOH solution was brought out of the glovebox and placed on the Schlenk line under N₂. The alcohol solution was adapted to the 12 L reaction pot using ⅜″ PTFE tubing and the alcohol solution added to the amide solution with vigorous stirring over the course of 30 minutes; resulting in an initial exotherm up to 25° C. as the first aliquot of alcohol was added, followed by a rapid decline to 18° C. which was maintained during continued alcohol addition. Upon complete addition of the alcohol solution, the reaction presented as a slightly turbid colorless solution and was stirred at room temperature for 12 hours, at which point, the volatiles were removed under reduced pressure using a water bath set to 50° C., with the Sn(O^{t}Bu)₄ product presenting as a colorless crystalline solid.

The reaction pot was outfitted with a jacketed U-joint equipped with a 1 L receiving flask. The apparatus was evacuated under reduced pressure, the transfer tube heated to 70° C., and the receiving flask cooled using a liquid N₂ bath. The product was warmed to 60° C. using a large heating mantle, whereby, the product had melted and solid was observed in the receiving flask (pressure of 600 mTorr) and a forecut collected from the crude material for approximately 20 minutes. The heating was suspended, the apparatus placed under N₂, and the receiving flask replaced with a 4-neck 5 L flask. The apparatus was placed back under reduced pressure, the 5 L flask cooled using liquid N₂, and the product warmed to 60° C., resulting in melting and product transfer as a colorless solid. Purification of the Sn(O^{t}Bu)₄ was carried out for 4 hours and 45 minutes, at which point the receiver flask was placed under N₂, warmed with a heat gun to remove external moisture, placed under vacuum, and brought into the nitrogen-filled glovebox for storage. Isolated 2538.83 g, 91.08% yield. The target molecule (Sn(O^{t}Bu)₄) was confirmed as synthesized by NMR which was consistent with reported literature values. Purity assigned as 99.57% by ¹H-NMR and >99% purity by ¹¹⁹Sn-NMR. ¹H{¹³C}-NMR (400 MHz, C₆D₆, 298K): 1.46 (s, 36H) ppm; ¹³C{¹H}-NMR (100 MHz, C₆D₆, 298K): 33.73, 74.66 ppm; ¹¹⁹Sn{¹H}-NMR (149 MHz, C₆D₆, 298K): −371.19 ppm. Melting Point (by DSC); 41.26° C.

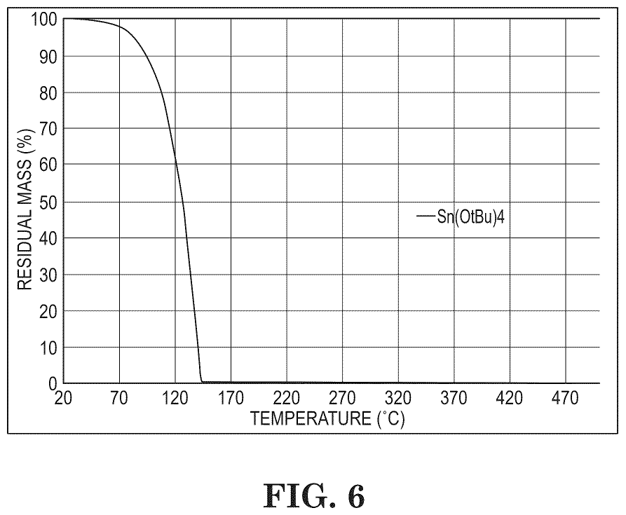

FIG. 6 is a graphical view of a thermogravimetric analysis of the Sn(O^{t}Bu)₄ product, according to some embodiments. The table presents a summary of chloride content (ppm) in commercially available Sn(O^{t}Bu)₄ and compares it to the chloride content (ppm) in Sn(O^{t}Bu)₄ synthesized according to the method described in this Example 1. As shown, the chloride content in the product synthesized in this Example 1 is several orders of magnitude less than the commercially available product.

Sn(OtBu)₄

| | Chloride content (ppm) |
|---|---|
| Commercial | 5237.35 |
| Example 1 | 1.9 |

### EXAMPLE 2

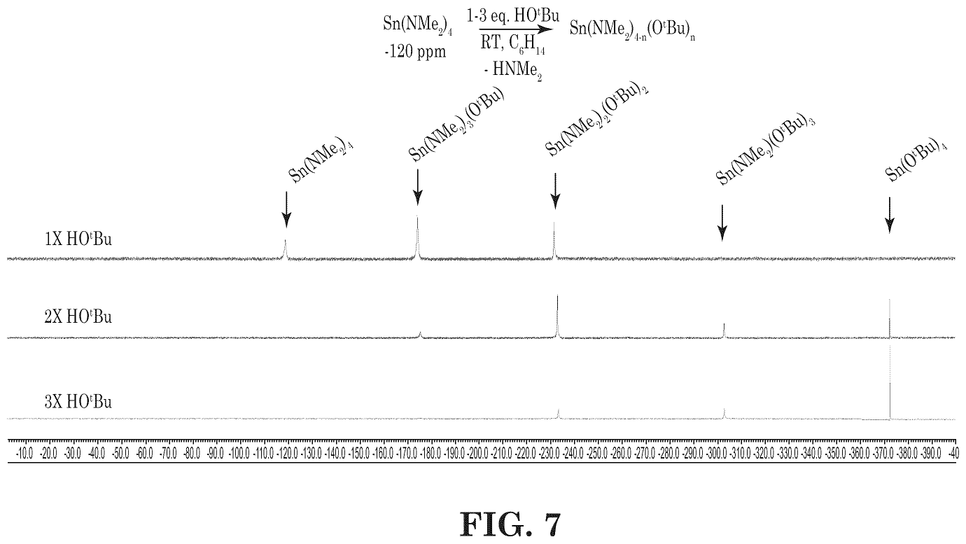

One to three (1-3) equivalents of tert-butanol were added to separate hexanes solutions of Sn(NMe₂)₄. The resulting colorless solutions were placed under reduced pressure, yielding colorless solids. The products were dissolved in C₆D₆ and comparison of the ¹¹⁹Sn-NMR chemical shifts displayed mixtures of Sn(O^{t}Bu)ₓ(NMe₂)_{y} species consistent with tert-butanol equivalents. ¹¹⁹Sn{¹H}-NMR (149 MHz, C₆D₆, 298K): Sn(O^{t}Bu)(NMe₂)₃: −174.39 ppm; Sn(O^{t}Bu)₂(NMe₂)₂: −232.15 ppm; Sn(O^{t}Bu)₃(NMe₂): −301.86 ppm. FIG. 7 is an NMR spectra of reaction products for varying amounts of HO^{t}Bu reagent, where A) 1 equivalent of HO^{t}Bu reagent, B) 2 equivalents of HO^{t}Bu reagent, and C) 3 equivalents of HO^{t}Bu reagent, according to some embodiments.

### EXAMPLE 3

### Synthesis of Sn(O^{t}Am)₄

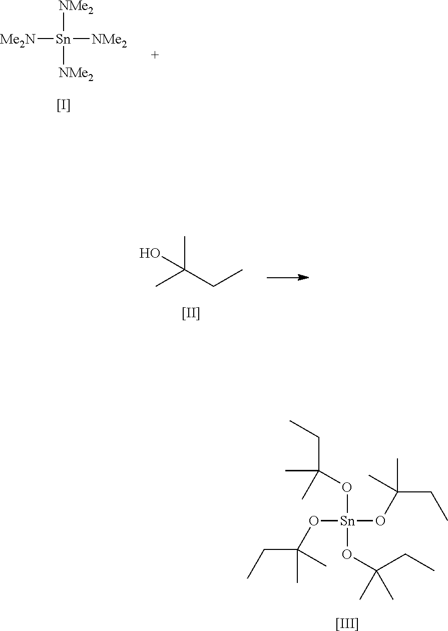

In a 100 mL flask tetrakis(dimethylamino)tin (10.0 g, 1 Eq, 33.9 mmol) was dissolved in ˜30 mL of hexanes. 2-methylbutan-2-ol (12.0 g, 4 Eq, 136 mmol) was added dropwise over ˜5 min. An exotherm was initially observed.

The solution was allowed to stir for ˜2 hours. ¹¹⁹Sn shows formation of a new product. No starting material was observed. The volatiles were then removed under vacuum with slight warming to 50° C. to drive off solvent and excess alcohol. Filtered the slightly hazy colorless solution through a 0.2 μm syringe filtered. Collected 15.0 g (94.7% yield) of product as a colorless clear liquid.

The crude material was distilled using a short path distillation head. The product was collected at 150 mTorr and head temperature of 80-85° C. A clear, colorless liquid was collected (12.7 g, 80% overall yield, purity by 119Sn: >99.9%)

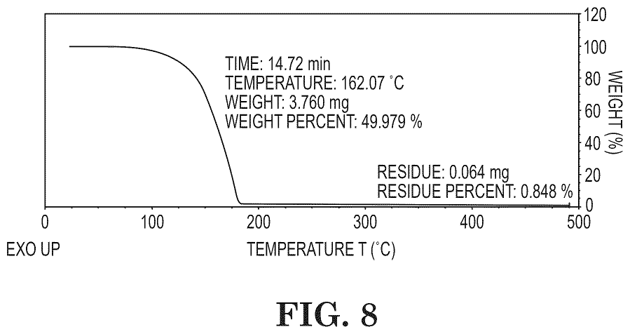

TGA of the distilled material showed a T_{1/2} of 162° C. and a residue <1%. See FIG. 8 which is a graphical view of a thermogravimetric analysis of the Sn(O^{t}Am)₄ product, according to some embodiments.

¹H-NMR (400 MHz, C₆D₆, 298K): 0.97 (t, 12H); 1.38 (s, 24H); 1.61 (q, 8H) ppm; ¹³C{¹H}-NMR (100 MHz, C₆D₆, 298K): 9.42; 31.24; 38.61; 76.54 ppm; ¹¹⁹Sn{¹H}-NMR (149 MHz, C₆D₆, 298K): −368.0 ppm.

### EXAMPLE 4

### Synthesis of Sn(O-secBu)₄

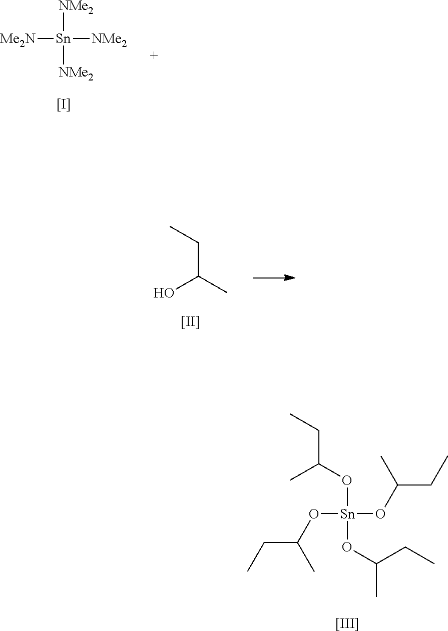

In a 100 mL flask tetrakis(dimethylamino)tin (10.0 g, 1 Eq, 33.9 mmol) was dissolved in ˜30 mL of hexanes. Butan-2-ol (10.0 g, 4 Eq, 136 mmol) was added dropwise over ˜20 min. An exotherm was initially observed.

The solution was allowed to stir for ˜1 hour. ¹¹⁹Sn shows formation of a new product. No starting material was observed. The volatiles were then removed under vacuum with slight warming to 50° C. to drive off solvent and excess alcohol. The crude material was a viscous cloudy liquid.

The crude material was distilled using a short path distillation head. The product was collected at 150 mTorr and head temperature of 103-108° C. A clear, colorless viscous liquid was collected.

TGA of the distilled material showed a T_{1/2} of 171.7° C. and a residue <1%.

¹H-NMR (400 MHz, C₆D₆, 298K): 0.90 (t, 12H); 1.33 (d, 12H); 1.65 (m, 4H) ppm; 1.75 (m, 4H); 4.23 (br s, 4H); ¹³C{¹H}-NMR (100 MHz, C₆D₆, 298K): 10.61; 23.87; 33.47; 73.80 ppm; ¹¹⁹Sn{¹H}-NMR (149 MHz, C₆D₆, 298K): −509.0 ppm.

### EXAMPLE 5

### Synthesis of Sn(3,3-dimethyl-2-butoxy)₄

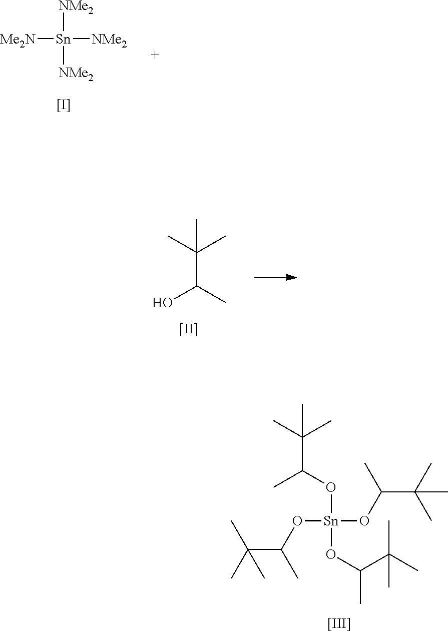

In a 100 mL flask tetrakis(dimethylamino)tin (10.0 g, 1 Eq, 33.9 mmol) was dissolved in ˜30 mL of hexanes. 3,3-dimethylbutan-2-ol (14.2 g, 4.1 Eq, 139 mmol) was added dropwise over ˜30 min. An exotherm was initially observed.

The solution was allowed to stir for ˜1 hour. ¹¹⁹Sn shows formation of a new product. No starting material was observed. The volatiles were then removed under vacuum with slight warming to 50° C. to drive off solvent and excess alcohol. The crude material was a slightly viscous cloudy liquid.

The crude material was distilled using a short path distillation head. The product was collected at 150 mTorr and head temperature of 100-103° C. A white solid began to collect so distillation was stopped due to clogging.

TGA of the purified material showed a melting point of 73C, T_{1/2} of 186.2° C. and a residue 1.2%.

¹H-NMR (400 MHz, C₆D₆, 298K): 0.94 (s, 36H); 1.27 (d, 12H); 3.92 (m, 4H); ¹³C{¹H}-NMR (100 MHz, C₆D₆, 298K): 21.05; 26.09; 36.68; 79.54 ppm; ¹¹⁹Sn{¹H}-NMR (149 MHz, C₆D₆, 298K): −361.6 ppm.

### EXAMPLE 6

### Synthesis of Sn(pentan-3-yloxy)₄

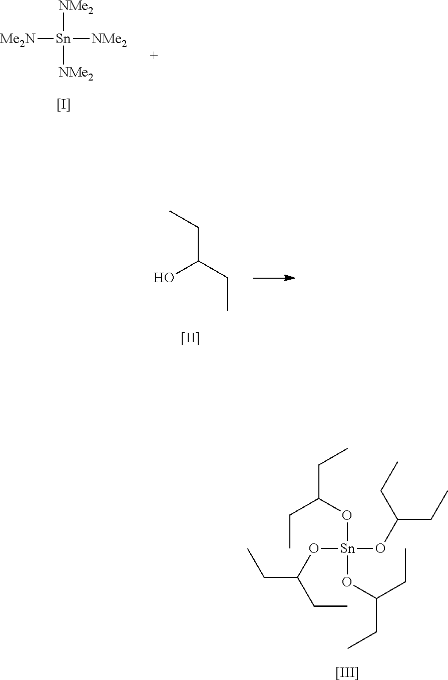

In a 100 mL flask tetrakis(dimethylamino)tin (10.0 g, 1 Eq, 33.9 mmol) was dissolved in ˜30 ml of hexanes. Pentan-3-ol (12.3 g, 4.1 Eq, 139 mmol) was added dropwise over ˜20 min. An exotherm was initially observed.

The solution was allowed to stir for ˜1 hour. ¹¹⁹Sn shows formation of a new product. No starting material was observed. The volatiles were then removed under vacuum with slight warming to 50° C. to drive off solvent and excess alcohol. The crude material was a colorless liquid.

The crude material was distilled using a short path distillation head. The product was collected at 150 mTorr and head temperature of 99-100° C. A white solid began to collect so distillation was stopped due to clogging. Remaining material was sublimated. Material appeared to melt at a temperature of ˜70-80° C. A crystalline white material was collected.

TGA of the purified material showed a T_{1/2} of 173.1° C. and a residue <1%.

¹H-NMR (400 MHz, C₆D₆, 298K): 1.03 (t, 24H); 1.78 (m, 16H); 4.14 (m, 4H) ppm; ¹³C{¹H}-NMR (100 MHz, C₆D₆, 298K): 10.32; 30.65; 78.80 ppm; ¹¹⁹Sn{¹H}-NMR (149 MHz, C₆D₆, 298K): −514.3 ppm.

### EXAMPLE 7

### Synthesis of Sn(O^{t}Bu)₄ from Sn(O₂CMe)₄ and NaO^{t}Bu

Sn(O₂CMe)₄ (1.0 g, 2.82 mmol) was loaded into a clear 40 mL vial equipped with a magnetic stir bar and diluted with THF (10 mL) to form a white suspension. NaO^{t}Bu (1.19 g, 12.4 mmol) was added to the mixture and the thick suspension stirred at 60° C. for 12 hours. The thick white suspension was cooled to room temperature (RT), dried under reduced pressure to yield a thick white gel-like material. The product was extracted with hexanes (10 mL) at 60° C., filtered through a 0.2 μm syringe filter, and the resulting colorless solution dried under reduced pressure to yield Sn(O^{t}Bu)₄ as a white solid. The product has been synthesized in >99.9% purity by ¹¹⁹Sn-NMR. ¹H{¹³C}-NMR (400 MHz, C₆D₆, 298K): 1.46 (s, 36H) ppm; ¹³C{¹H}-NMR (100 MHz, C₆D₆, 298K): 33.73, 74.66 ppm; ¹¹⁹Sn{¹H}-NMR (149 MHz, C₆D₆, 298K): −371.19 ppm.

### EXAMPLE 8

Sn⁰ and di-tert-butyl peroxide (^{t}BuO-O^{t}Bu) are added to a clear 40 mL vial and stirred to form a reaction mixture. A solvent is added. Upon exposure of the reaction mixture to light, the Sn metal and di-tert-butyl peroxide react to directly form a reaction product comprising Sn(O^{t}Bu)₄.

### EXAMPLE 9

Sn⁰ and di-tert-butyl peroxide (^{t}BuO-O^{t}Bu) are added to a clear 40 mL vial and stirred to form a reaction mixture. No solvent is added. Upon exposure of the reaction mixture to light, the Sn metal and di-tert-butyl peroxide react to directly form a reaction product comprising Sn(O^{t}Bu)₄.

### EXAMPLE 10

Sn⁰ and di-tert-butyl peroxide (^{t}BuO-O^{t}Bu) are added to a clear 40 mL vial and stirred to form a reaction mixture. A solvent is added. The Sn metal and di-tert-butyl peroxide react to directly form a reaction product comprising Sn(O^{t}Bu)₄.

### EXAMPLE 11

Sn⁰ and di-tert-butyl peroxide (^{t}BuO-O^{t}Bu) are added to a clear 40 mL vial and stirred to form a reaction mixture. No solvent is added. The Sn metal and di-tert-butyl peroxide react to directly form a reaction product comprising Sn(O^{t}Bu)₄.

### EXAMPLE 12

Sn metal and di-tert-butyl peroxide are added to a clear 40 mL vial and stirred to form a reaction mixture. A solvent is added. Upon heating of the reaction mixture, the Sn metal and di-tert-butyl peroxide react to form a reaction product comprising Sn(O′Bu)₄.

### EXAMPLE 13

Sn metal and di-tert-butyl peroxide are added to a clear 40 mL vial and stirred to form a reaction mixture. No solvent is added. Upon heating of the reaction mixture, the Sn metal and di-tert-butyl peroxide react to form a reaction product comprising Sn(O′Bu)₄.

### EXAMPLE 14

SnO is reacted with a carboxylic acid with a solvent at elevated temperature to yield Sn(O₂CR)₄ compounds in a halide-free reaction.

### EXAMPLE 15

SnO is reacted with a carboxylic acid without a solvent at elevated temperature to yield Sn(O₂CR)₄ compounds in a halide-free reaction.

### EXAMPLE 16

SnO₂ is reacted with a carboxylic acid with at elevated temperature to yield Sn(O₂CR)₄ compounds in a halide-free reaction.

### EXAMPLE 17

SnO₂ is reacted with a carboxylic acid without a solvent at elevated temperature to yield Sn(O₂CR)₄ compounds in a halide-free reaction.

### EXAMPLE 18

SnI₄ is used as a starting material so that the resulting products (e.g. H₂NEt₂I) are not as volatile as the chloride analogs and do not contribute to the impurity profile of the product.

### EXAMPLE 19

A bulky amine (e.g., pyridine, PMDETA) or other base is used to limit chloride transfer to product.

### ASPECTS

Various Aspects are described below. It is to be understood that any one or more of the features recited in the following Aspect(s) can be combined with any one or more other Aspect(s).

Aspect 1. A composition comprising:
a tin (IV) alkoxide compound of the formula:

Sn(OR¹)₄,
where:
   R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof,
wherein a purity of the tin (IV) compound in the composition is at least 95%.

Aspect 2. The composition according to Aspect 1, wherein each R¹ is the same.

Aspect 3. The composition according to any one of Aspects 1-2, wherein R¹ is a C₁-C₈ alkyl.

Aspect 4. The composition according to any one of Aspects 1-3, wherein R¹ is a C₁-C₄ alkyl.

Aspect 5. The composition according to any one of Aspects 1-4, where the tin (IV) alkoxide compound comprises a compound of the formula: Sn(OC(CH₃)₃)₄.

Aspect 6. The composition according to any one of Aspects 1-5, wherein the tin (IV) alkoxide compound is present in the composition at a purity of 95% to 99.9% as determined by ¹H-NMR.

Aspect 7. The composition according to any one of Aspects 1-6, wherein the tin (IV) alkoxide compound is present in the composition at a purity of at least 99.5% as determined by ¹H-NMR.

Aspect 8. The composition according to any one of Aspects 1-7, wherein the composition comprises less than 10 ppb of a nitrogen-containing impurity as determined by inductively coupled plasma mass spectrometry.

Aspect 9. The composition according to any one of Aspects 1-8, wherein the composition comprises less than 10 ppb of a halide impurity as determined by ion chromatography.

Aspect 10. The composition according to any one of Aspects 1-9, wherein the tin (IV) alkoxide compound comprises an anhydrous tin (IV) alkoxide compound.

Aspect 11. A composition comprising:
a tin (IV) alkoxide compound of the formula:

Sn(OR¹)ₙ(OR)₄₋ₙ,
where:
   R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof,
wherein a purity of the tin (IV) alkoxide compound in the composition is at least 95%.

Aspect 12. The composition according to Aspect 11, wherein each R¹ is the same, and/or wherein at least one R and at least one R¹ are different.

Aspect 13. The composition according to any one of Aspects 11-12, wherein R¹ is a C₁-C₈ alkyl.

Aspect 14. The composition according to any one of Aspects 11-13, wherein R¹ is a C₁-C₄ alkyl.

Aspect 15. The composition according to any one of Aspects 11-14, where the tin (IV) alkoxide compound comprises at least one of Sn(O₂CCH₃)₃(O^{t}Bu), Sn(O₂CCH₃)₂(O^{t}Bu)₂, Sn(O₂CCH₃)(O^{t}Bu)₃, or any combination thereof.

Aspect 16. The composition according to any one of Aspects 11-15, wherein the tin (IV) alkoxide compound is present in the composition at a purity of 95% to 99.9% as determined by ¹H-NMR.

Aspect 17. The composition according to any one of Aspects 11-16, wherein the tin (IV) alkoxide compound is present in the composition at a purity of at least 99.5% as determined by ¹H-NMR.

Aspect 18. The composition according to any one of Aspects 11-17, wherein the composition comprises less than 10 ppb of a nitrogen-containing impurity as determined by inductively coupled plasma mass spectrometry.

Aspect 19. The composition according to any one of Aspects 11-18, wherein the composition comprises less than 10 ppb of a halide impurity as determined by ion chromatography.

Aspect 20. The composition according to any one of Aspects 11-19, wherein the tin (IV) alkoxide compound comprises an anhydrous tin (IV) alkoxide compound.

Aspect 21. A method comprising:
contacting a tin (IV) carboxylate compound with a reagent to form a tin (IV) alkoxide compound,
   wherein the tin (IV) carboxylate compound comprises a compound of the formula:

Sn(O₂CR)₄,
where:
   R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
wherein the reagent comprises a compound of the formula:

MOR¹,
where:
   M is an alkali metal cation, an alkaline earth metal cation, a transition metal cation, or a post-transition metal cation;
   R¹ comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
wherein the tin (IV) alkoxide compound comprises a compound of the formula:

Sn(OR¹)₄,
where:
   R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

Aspect 22. The method according to Aspect 21, wherein each R is the same.

Aspect 23. The method according to any one of Aspects 21-22, wherein R is a C₁-C₈ alkyl.

Aspect 24. The method according to any one of Aspects 21-23, wherein R is a C₁-C₄ alkyl.

Aspect 25. The method according to any one of Aspects 21-24, wherein each R¹ is the same.

Aspect 26. The method according to any one of Aspects 21-25, wherein R¹ is a C₁-C₈ alkyl.

Aspect 27. The method according to any one of Aspects 21-26, wherein R¹ is a C₁-C₄ alkyl.

Aspect 28. The method according to any one of Aspects 21-27, wherein the tin (IV) carboxylate compound comprises at least one of Sn(O₂CH)₄, Sn(O₂CCH₃)₄, Sn(O₂CCH₂CH₃)₄, Sn(O₂C(CH₂)₂CH₃)₄, Sn(O₂C(CH₂)₃CH₃)₄, Sn(O₂CCH(CH₃)₂)₄, Sn(O₂CCH₂CH(CH₃)₂)₄, or any combination thereof.

Aspect 29. The method according to any one of Aspects 21-28, wherein the reagent comprises at least one of NaOC(CH₃)₃, KOC(CH₃)₃, LiOC(CH₃)₃, ZnOC(CH₃)₃, MgOC(CH₃)₃, or any combination thereof.

Aspect 30. The method according to any one of Aspects 21-29, wherein the contacting is performed under heating to a temperature of 30° C. to 200° C.

Aspect 31. The method according to any one of Aspects 21-30, wherein the contacting is performed in a presence of a solvent.

Aspect 32. The method according to any one of Aspects 21-31, wherein the contacting is performed in a presence of a tetrahydrofuran.

Aspect 33. The method according to any one of Aspects 21-32, wherein the tin (IV) carboxylate compound comprises Sn(N(CH₃)₂)₄.

Aspect 34. The method according to any one of Aspects 21-33, further comprising:
contacting a tin metal with a carboxylate compound to obtain the tin (IV) carboxylate compound,
   wherein the tin metal comprises Sn;
   wherein the carboxylate compound comprises a compound of the formula:

RCO₂H,
where:
   R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

Aspect 35. The method according to any one of Aspects 21-34, further comprising:
contacting a tin oxide compound with a carboxylate compound to obtain the tin (IV) carboxylate compound,
   wherein the tin oxide compound comprises a compound of the formula: SnO;
   wherein the carboxylate compound comprises a compound of the formula:

RCO₂H,
where:
   R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

Aspect 36. The method according to any one of Aspects 21-35, further comprising:
contacting a tin oxide compound with a carboxylate compound to obtain the tin (IV) carboxylate compound,
   wherein the tin oxide compound comprises a compound of the formula: SnO₂;
   wherein the carboxylate compound comprises a compound of the formula:

RCO₂H,
where:
   R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

Aspect 37. The method according to any one of Aspects 21-36, further comprising:
contacting a tin compound with a carboxylate compound to obtain the tin (IV) carboxylate compound,
   wherein the tin compound comprises a compound of the formula:

Sn(R′)₄,
where:
   R′ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
wherein the carboxylate compound comprises a compound of the formula:

RCO₂H,
where:
   R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

Aspect 38. The method according to Aspect 37, wherein R′ comprises at least one of an alkenyl, an aryl, or any combination thereof.

Aspect 39. The method according to Aspect 37, wherein R′ is a vinyl, a phenyl, a benzyl, a benzoyl, or any combination thereof, wherein R′ is optionally substituted with at least one alkyl.

Aspect 40. The method according to any one of Aspects 21-39, wherein the tin (IV) alkoxide compound comprises less than 10 ppb of a nitrogen-containing impurity as determined by inductively coupled plasma mass spectrometry.

Aspect 41. The method according to any one of Aspects 21-40, wherein the tin (IV) alkoxide compound comprises less than 10 ppb of a halide impurity as determined by ion chromatography.

Aspect 42. A method comprising:
contacting a tin (IV) amide compound with a reagent to form a tin (IV) alkoxide compound,
   wherein the tin (IV) amide compound comprises a compound of the formula:

Sn(NR₂)₄,
where:
   R independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
wherein the reagent comprises a compound of the formula:

HOR¹,
where:
   R¹ comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof;
wherein the tin (IV) alkoxide compound comprises a compound of the formula:

Sn(OR¹)₄,
where:
   R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof.

Aspect 43 The method according to Aspect 42, wherein the tin (IV) amide compound comprises Sn(N(CH₃)₂)₄.

Aspect 44. The method according to Aspect 42, wherein each R is the same.

Aspect 45. The method according to any one of Aspects 42-44, wherein R is a C₁-C₈ alkyl.

Aspect 46. The method according to any one of Aspects 42-45, wherein R is a C₁-C₄ alkyl.

Aspect 47. The method according to any one of Aspects 42-46, wherein each R¹ is the same.

Aspect 48. The method according to any one of Aspects 42-47, wherein R¹ is a C₁-C₈ alkyl.

Aspect 49. The method according to any one of Aspects 42-48, wherein R¹ is a C₁-C₄ alkyl.

Aspect 50. The method according to any one of Aspects 42-49, wherein the tin (IV) amide compound comprises Sn(N(CH₃)₂)₄.

Aspect 51. The method according to any one of Aspects 42-50, wherein the reagent comprises HOC(CH₃)₃.

Aspect 52. The method according to any one of Aspects 42-51, wherein the tin (IV) amide compound is contacted with one to three equivalents of HOR¹.

Aspect 53. The method according to Aspect 52, further comprising forming a compound of the formula:

Sn(NR₂)₄₋ₙ(OR¹)ₙ.

Aspect 54. The method according to Aspect 52, further comprising forming a compound of the formula:

Sn(NR₂)₃(OR¹).

Aspect 55. The method according to Aspect 52, further comprising forming a compound of the formula:

Sn(NR₂)₂(OR¹)₂.

Aspect 56. The method according to Aspect 54, further comprising forming a compound of the formula:

Sn(NR₂)(OR¹)₃.

Aspect 57. The method according to any one of Aspects 42-56, wherein the tin (IV) amide compound is contacted with at least three equivalents of HOR¹.

Aspect 58. The method according to any one of Aspects 42-57, wherein the contacting is performed under heating to a temperature of 30° C. to 200° C.

Aspect 59. The method according to any one of Aspects 42-58, wherein the contacting is performed in a presence of a solvent.

Aspect 60. The method according to any one of Aspects 42-59, wherein the tin (IV) alkoxide compound has a purity of at least 99.5% as determined by ¹H-NMR.

Aspect 61. The method according to any one of Aspects 42-60, wherein the tin (IV) alkoxide compound comprises less than 10 ppb of a nitrogen-containing impurity as determined by inductively coupled plasma mass spectrometry.

Aspect 62. The method according to any one of Aspects 42-61, wherein the tin (IV) alkoxide compound comprises less than 10 ppb of a halide impurity as determined by ion chromatography.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A composition comprising:
a tin (IV) alkoxide compound of the formula:
Sn(OR¹)₄,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof,
wherein a purity of the tin (IV) compound in the composition is at least 95%.

2. The composition of claim 1, wherein each R¹ is the same.

3. The composition of claim 1, wherein R¹ is a C₁-C₈ alkyl.

4. The composition of claim 1, wherein R¹ is a C₁-C₄ alkyl.

5. The composition of claim 1, where the tin (IV) alkoxide compound comprises a compound of the formula: Sn(OC(CH₃)₃)₄.

6. The composition of claim 1, wherein the tin (IV) alkoxide compound is present in the composition at a purity of 95% to 99.9% as determined by ¹H-NMR.

7. The composition of claim 1, wherein the tin (IV) alkoxide compound is present in the composition at a purity of at least 99.5% as determined by ¹H-NMR.

8. The composition of claim 1, wherein the composition comprises less than 10 ppb of a nitrogen-containing impurity as determined by inductively coupled plasma mass spectrometry.

9. The composition of claim 1, wherein the composition comprises less than 10 ppb of a halide impurity as determined by ion chromatography.

10. The composition of claim 1, wherein the tin (IV) alkoxide compound comprises an anhydrous tin (IV) alkoxide compound.

11. A composition comprising:
a tin (IV) alkoxide compound of the formula:
Sn(OR¹)ₙ(OR)₄₋ₙ,
where:
R¹ independently comprises at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, an indenyl, or any combination thereof,
wherein a purity of the tin (IV) alkoxide compound in the composition is at least 95%.

12. The composition of claim 11, wherein at least one R and at least one R¹ are different.

13. The composition of claim 11, wherein R¹ is a C₁-C₈ alkyl.

14. The composition of claim 11, wherein R¹ is a C₁-C₄ alkyl.

15. The composition of claim 11, where the tin (IV) alkoxide compound comprises at least one of Sn(O₂CCH₃)₃(O^{t}Bu), Sn(O₂CCH₃)₂(O^{t}Bu)₂, Sn(O₂CCH₃)(O^{t}Bu)₃, or any combination thereof.

16. The composition of claim 11, wherein the tin (IV) alkoxide compound is present in the composition at a purity of 95% to 99.9% as determined by ¹H-NMR.

17. The composition of claim 11, wherein the tin (IV) alkoxide compound is present in the composition at a purity of at least 99.5% as determined by ¹H-NMR.

18. The composition of claim 11, wherein the composition comprises less than 10 ppb of a nitrogen-containing impurity as determined by inductively coupled plasma mass spectrometry.

19. The composition of claim 11, wherein the composition comprises less than 10 ppb of a halide impurity as determined by ion chromatography.

20. The composition of claim 11, wherein the tin (IV) alkoxide compound comprises an anhydrous tin (IV) alkoxide compound.
